(19) United States
(12) Patent Application Publication
(10) Pub. No.: US 2024/0429235 A1
(43) Pub. Date: Dec. 26, 2024

(54) COMPLEMENTARY FIELD-EFFECT TRANSISTOR WITH FORKED SEMICONDUCTOR STRUCTURE

(71) Applicant: Intel Corporation, Santa Clara, CA (US)

(72) Inventors: Bilal Chehab, Portland, OR (US); Changyok Park, Portland, OR (US); Tuhin Guha Neogi, Sherwood, OR (US); George Joseph Sacks, Ridgefield, WA (US); Christophe Berteau-Pavy, Portland, OR (US)

(73) Assignee: Intel Corporation, Santa Clara, CA (US)

(21) Appl. No.: 18/337,697

(22) Filed: Jun. 20, 2023

(51) Int. Cl. H01L 27/092; H01L 29/06; H01L 29/417; H01L 29/778; H01L 29/786

(52) U.S. Cl. CPC H01L 27/092; H01L 29/0665; H01L 29/41775; H01L 29/778; H01L 29/78696

(57) ABSTRACT

A CFET may include two or more transistors stacked over each other. A transistor may be a FET including a forked semiconductor structure. The source region and drain region of a transistor may have a forked shape including a body and one or more branches protruding from the body. A branch may include a fin, nanoribbon, etc. The channel region may be between a branch of the source region and a branch of the drain region. The body of the source region and the body of the drain region may be on opposite sides of the channel region in two perpendicular directions. The two bodies may be diagonally arranged with respect to the channel region. The body of the source region or drain region may be over a contact that is electrically coupled to a frontside metal layer or a backside metal layer for signal transmission or power delivery.

### BACKGROUND

Integrated circuit (IC) fabrication usually includes two stages. The first stage is referred to as the front-end of line (FEOL). The second stage is referred to as the back-end of line (BEOL). In the FEOL, individual semiconductor devices components (e.g., transistor, capacitors, resistors, etc.) can be patterned in a wafer. In the BEOL, metal layers, vias, and insulating layers can be formed to get the individual components interconnected. The BEOL usually starts with forming the first metal layer on the wafer. The first metal layer is often called M0. More metal layers can be formed on top of M0, and these metal layers are often called M1, M2, and so on.

standard cell methodology is a popular method of designing IC devices, such as application-specific ICs. A standard cell usually includes a group of transistors and interconnect structures. A standard cell may provide a logic function (e.g., AND, OR, XOR, etc.), storage function (e.g., flipflop, latch, etc.), other types of functions, or some combination thereof. The height of a standard cell, which is the dimension along the vertical axis, may be defined as the number of metal tracks of the first metal layer (M0) that can fit inside the standard cell. The width of a standard cell, which is the dimension along the horizontal axis, may be defined as the number of poly (polycrystalline silicon) in the horizontal axis. The distance between two parallel poly that are immediately adjacent to each other is referred to as the contacted poly pitch (CPP). Scaling of the area of a standard cell, such as scaling the cell height and CPP, can be important to increase the number of transistors in the IC.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1C illustrate an example field-effect transistor (FET) with forked semiconductor structures, according to some embodiments of the disclosure.

FIGS. 2A and 2B illustrate another example FET with forked semiconductor structures, according to some embodiments of the disclosure.

FIGS. 3A-3E illustrate an IC device including a complementary FET (CFET) with a forked semiconductor structure, according to some embodiments of the disclosure.

FIGS. 4A-4C illustrate an example standard cell including the CFET and having pin access in M1, according to some embodiments of the disclosure.

FIGS. 5A-5C illustrate another example standard cell including the CFET and having pin access in M1, according to some embodiments of the disclosure.

FIGS. 6A-6E illustrate an example standard cell including a hybrid CFET and having pin access in M0, according to some embodiments of the disclosure.

FIGS. 7A-7E illustrate another example standard cell including a hybrid CFET and having pin access in M0, according to some embodiments of the disclosure.

FIGS. 8A-8E illustrate yet another example standard cell including a hybrid CFET and having pin access in M0, according to some embodiments of the disclosure.

FIGS. 9A-9F illustrate an IC device including a plurality of CFETs with forked semiconductor structures, according to some embodiments of the disclosure.

FIGS. 10A-10B are top views of a wafer and dies that may include CFET with forked semiconductor structures, according to some embodiments of the disclosure.

FIG. 11 is a side, cross-sectional view of an example IC package that may include one or more IC devices having CFET with forked semiconductor structures, according to some embodiments of the disclosure.

FIG. 12 is a cross-sectional side view of an IC device assembly that may include components having one or more IC devices implementing CFET with forked semiconductor structure, according to some embodiments of the disclosure.

FIG. 13 is a block diagram of an example computing device that may include one or more components with CFET with forked semiconductor structure, according to some embodiments of the disclosure.

### DETAILED DESCRIPTION

The systems, methods, and devices of this disclosure each have several innovative aspects, no single one of which is solely responsible for all the desirable attributes disclosed herein. Details of one or more implementations of the subject matter described in this specification are set forth in the description below and the accompanying drawings.

A CFET architecture usually has NMOS (N-type metal-oxide-semiconductor) and PMOS (P-type metal-oxide-semiconductor) devices stacked on top of each other. CFET device can help with scaling the height of the standard cell. However, due to the tall structure, it can result in process complexity as well as high gate capacitance. Other types of FET architecture have been proposed, such as double-forked (E₂) FET and double-forked dynamically doped (E₂D₂) FET. Even though these FET architectures device can support a CPP scaling with reduction of gate cap, they can result in complex standard cell routability and large cell height (e.g., in a direction along Y-axis).

Embodiments of the present disclosure may improve on at least some of the challenges and issues described above by providing CFETs with forked semiconductor structure structures. An example monolithic CFET architecture in the present disclosure may include a stack of two transistors, each of which may have two forked semiconductor structures that are misaligned along either the vertical axis or the horizontal axis of the standard cell. The CFET architecture can facilitate backside power delivery, e.g., with direct contact to the forked semiconductor structures from the backside.

In various embodiments of the present disclosure, a CFET may include a first transistor stacked over a second transistor. In an embodiment, the first transistor is an NMOS transistor, and the second transistor is a PMOS transistor. In another embodiment, the first transistor is a PMOS transistor, and the second transistor is a NMOS transistor. In yet another embodiment, both the first transistor and the second transistor are PMOS or NMOS transistors. The first transistor includes a first source region, a first drain region, a first channel region, and a first gate. The second transistor includes a second source region, a second drain region, a second channel region, and a second gate. The source or drain region in each transistor may have a forked structure, which includes a body and a branch section. The branch section includes one or more branches extending from a surface of the body. A branch may be a fin, nanoribbon, etc. The first gate may be over the second gate in a first direction, e.g., a direction along the vertical axis (e.g., Z axis) of the standard cell. The first gate or the second gate may include one or more gate electrodes, which may be separated from each other by a dielectric material. The first gate may be separated from the second gate by an insulative structure.

The first gate and second gate may be in a gate assembly that is between the branch section of a source region and the branch section of the drain region of the same transistor, e.g., in a direction along the horizontal axis (e.g., Y axis) of the standard cell. The gate assembly may be between two dielectric structures. The first gate and second gate may be between the two dielectric structures in a direction along an axis (e.g., X axis) that is perpendicular to the vertical axis and the horizontal axis of the standard cell. In some embodiments, a portion of a dielectric structure may be over a portion of the body of a source region or a drain region. The dielectric structures may prevent shortage between the gates and the source/drain contacts. For each transistor, the body of the source region and the body of the drain region may be at opposite sides of the gate assembly along both the X axis and the Y axis. For instance, the body of the source region and the body of the drain region are diagonally arranged relative to the gate assembly.

Such a CFET architecture can reduce gate cap as the source/drain and gate are on different planes. Also, the architecture can support significant or extreme CPP scaling due to lower gate spacer. With such CFET architecture, standard cell can be scaled to three M0 routing tracks. The CFET architecture can also provide easy access from the backside to both the bottom and the top device through direct contact. Low aspect ratio via from the backside can be implemented to access the top device with lower via resistance. Also, low aspect ratio via from the frontside can be implemented to access the top device with lower via resistance. Therefore, IC devices including CFETs with forked semiconductor structures in the present disclosure can have better performance than currently available IC devices.

It should be noted that, in some settings, the term “nanoribbon” has been used to describe an elongated semiconductor structure that has a substantially rectangular transverse cross-section (e.g., a cross-section in a plane perpendicular to the longitudinal axis of the structure), while the term “nanowire” has been used to describe a similar structure but with a substantially circular or square transverse cross-sections. In the following, a single term “nanoribbon” is used to describe an elongated semiconductor structure independent of the shape of the transverse cross-section. Thus, as used herein, the term “nanoribbon” is used to cover elongated semiconductor structures that have substantially rectangular transverse cross-sections (possibly with rounded corners), elongated semiconductor structures that have substantially square transverse cross-sections (possibly with rounded corners), elongated semiconductor structures that have substantially circular or elliptical/oval transverse cross-sections, as well as elongated semiconductor structures that have any polygonal transverse cross-sections.

In the following, some descriptions may refer to a particular source or drain (S/D) region or contact being either a source region/contact or a drain region/contact. However, unless specified otherwise, which region/contact of a transistor or diode is considered to be a source region/contact and which region/contact is considered to be a drain region/contact is not important because, as is common in the field of FETs, designations of source and drain are often interchangeable. Therefore, descriptions of some illustrative embodiments of the source and drain regions/contacts provided herein are applicable to embodiments where the designation of source and drain regions/contacts may be reversed.

As used herein, the term “metal layer” may refer to a layer above a substrate that includes electrically conductive interconnect structures for providing electrical connectivity between different IC components. Metal layers described herein may also be referred to as “interconnect layers” to clearly indicate that these layers include electrically conductive interconnect structures which may, but do not have to be, metal.

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art. For example, the term “connected” means a direct electrical or magnetic connection between the things that are connected, without any intermediary devices, while the term “coupled” means either a direct electrical or magnetic connection between the things that are connected, or an indirect connection through one or more passive or active intermediary devices. The term “circuit” means one or more passive and/or active components that are arranged to cooperate with one another to provide a desired function. If used, the terms “oxide,” “carbide,” “nitride,” etc. refer to compounds containing, respectively, oxygen, carbon, nitrogen, etc., the term “high-k dielectric” refers to a material having a higher dielectric constant (k) than silicon oxide, while the term “low-k dielectric” refers to a material having a lower k than silicon oxide. The terms “substantially,” “close,” “approximately,” “near,” and “about,” generally refer to being within +/−10%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−8% of a target value, e.g., within +/−5% of a target value or within +/−2% of a target value, based on the context of a particular value as described herein or as known in the art. Also, the term “or” refers to an inclusive “or” and not to an exclusive “or.”

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening layers.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C).

The description may use the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

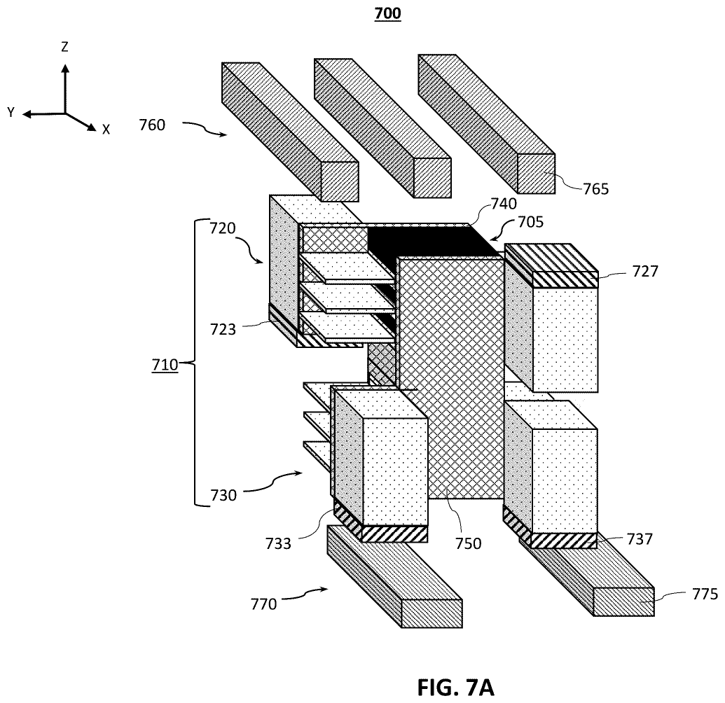

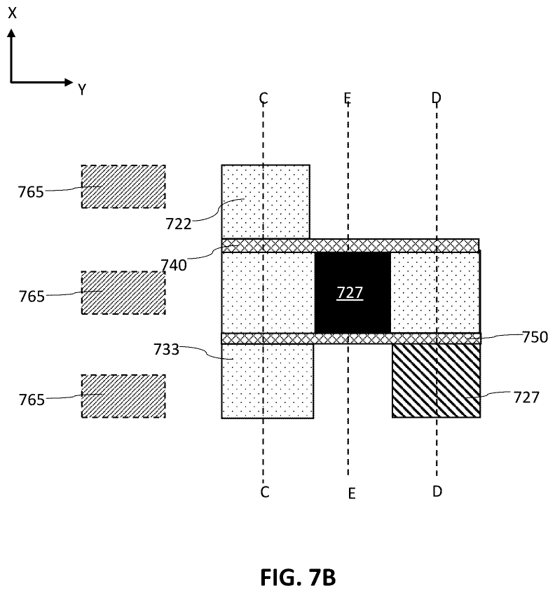

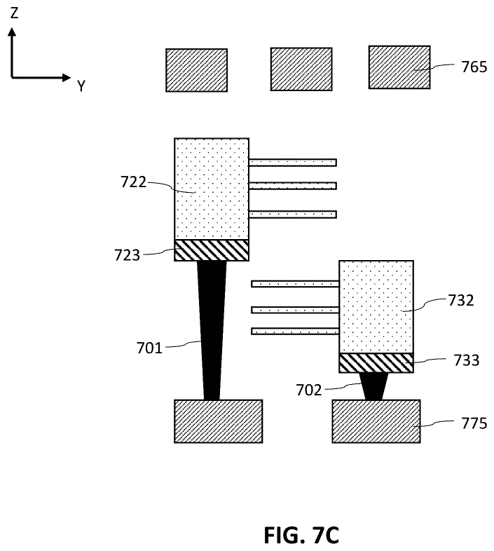

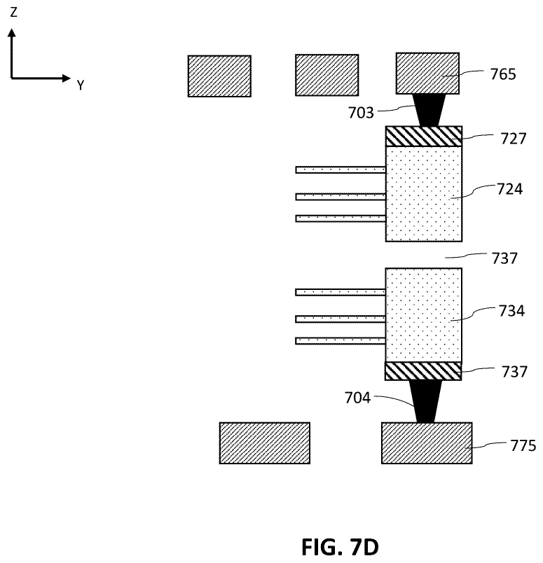

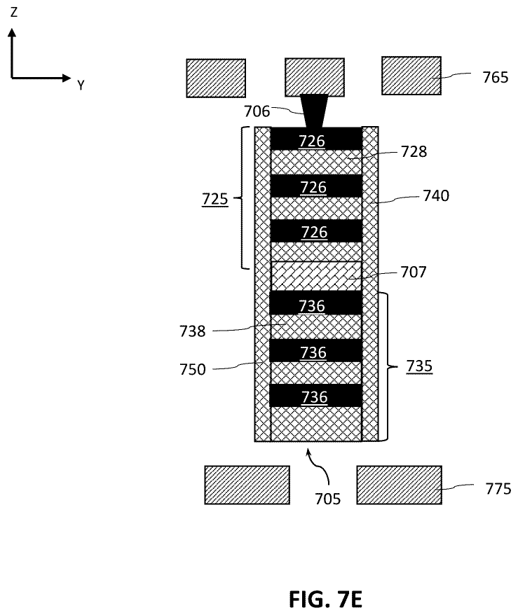

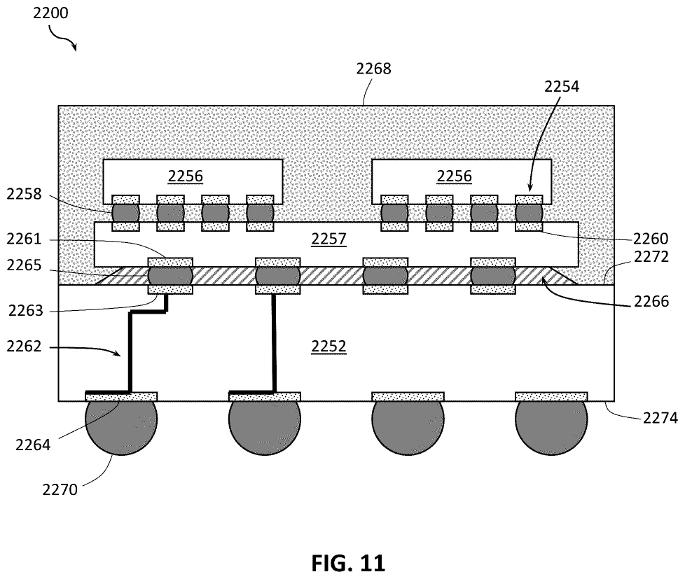

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense. For convenience, if a collection of drawings designated with different letters are present, e.g., FIGS. 7A-7B, such a collection may be referred to herein without the letters, e.g., as “FIG. 11.”

In the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of CFET with forked semiconductor structures as described herein.

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation.

Operations described may be performed in a different order from the described embodiment. Various additional operations may be performed, and/or described operations may be omitted in additional embodiments.

Various IC devices with CFET with forked semiconductor structure as described herein may be implemented in, or associated with, one or more components associated with an IC or/and may be implemented between various such components. In various embodiments, components associated with an IC include, for example, transistors, diodes, power sources, resistors, capacitors, inductors, sensors, transceivers, receivers, antennas, etc. Components associated with an IC may include those that are mounted on IC or those connected to an IC. The IC may be either analog or digital and may be used in a number of applications, such as microprocessors, optoelectronics, logic blocks, audio amplifiers, etc., depending on the components associated with the IC. The IC may be employed as part of a chipset for executing one or more related functions in a computer.

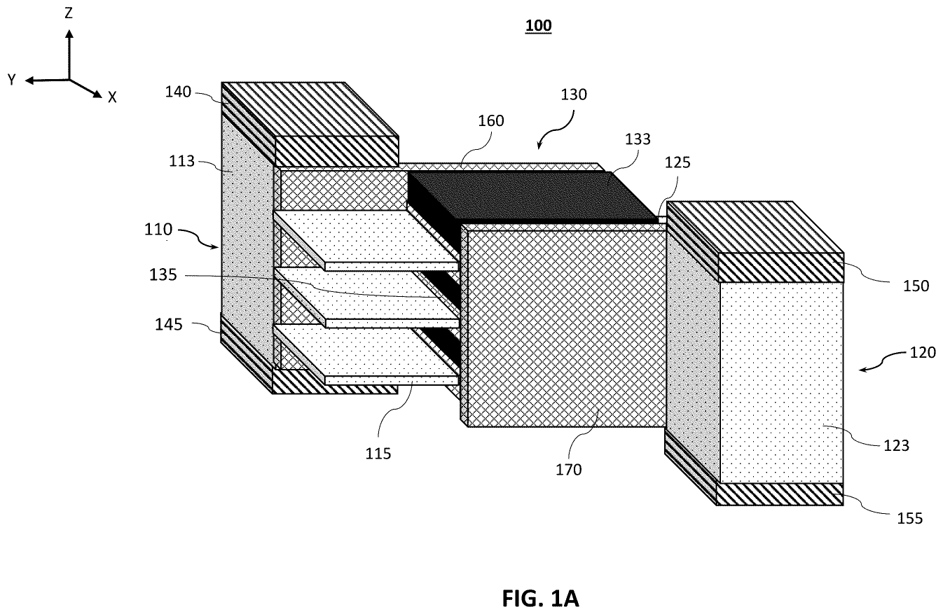

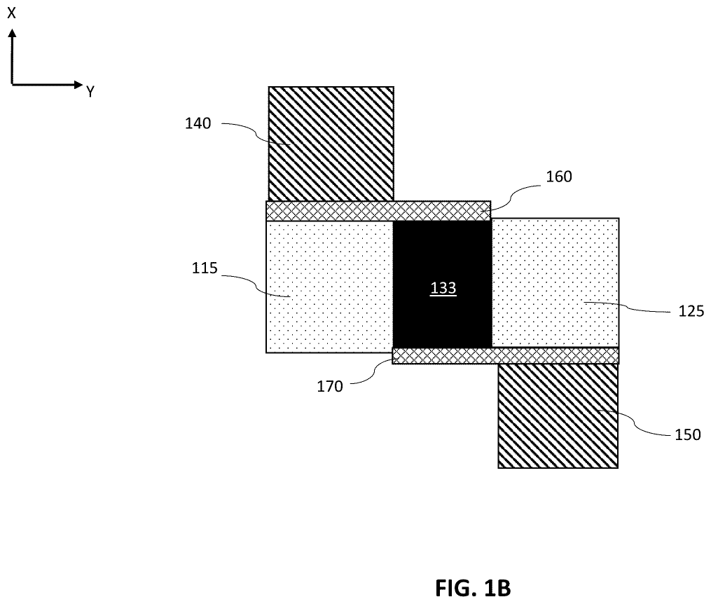

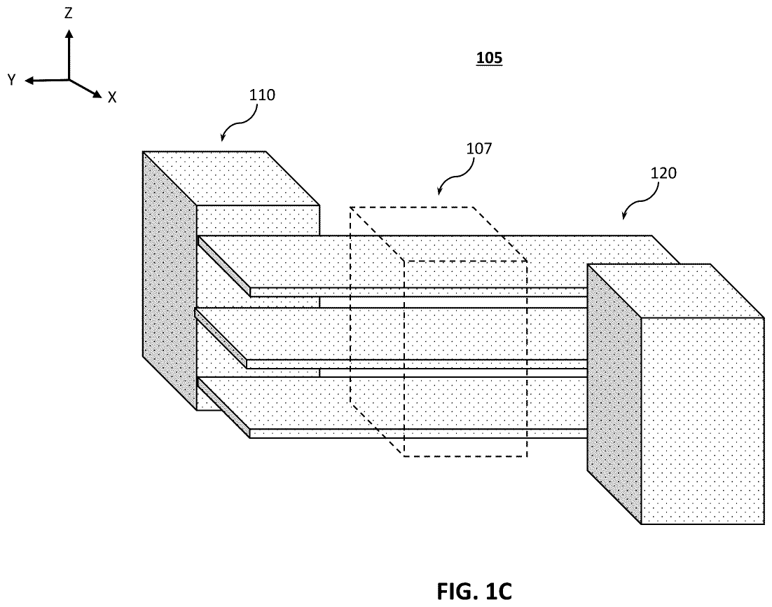

FIGS. 1A-1C illustrate an example FET 100 with a forked semiconductor structure 105 105, according to some embodiments of the disclosure. FIG. 1A is a perspective view of the FET 100. FIG. 1B is a top view of the FET 100. FIG. 1C is a perspective view of the forked semiconductor structure 105. The FET 100 may be a P-type transistor (e.g., a PMOS transistor) or an N-type transistor (e.g., an NMOS transistor). The forked semiconductor structure 105 in the FET 200 includes a source region 110 and a drain region 120. The forked semiconductor structure 105 also includes a channel region 107 that is between the source region 110 and drain region 120. The channel region 107 is shown in FIG. 1C. Please note that the dashed cuboid in FIG. 1C is for indicating the position of the channel region 107 and is not part of the channel region 107. The FET 100 also includes a gate assembly 130, source contacts 140 and 145, drain contacts 150 and 155, and dielectric layers 160 and 170. In other embodiments, the FET 100 may include different, fewer, or more components.

As shown in FIG. 1A, the source region 110 has a fork shape, i.e., the source region 110 is a forked region. The source region 110 includes a body section (“body”) 113 and three branch sections (“branches”) 115 (individually referred to as “branch section 115” or “branch 115”). The branches 115 are stacked along the Z axis. Even though FIG. 1A shows three branches 115, the source region 110 may include a different number of branches 115 in other embodiments. A branch 115 may be a fin or nanoribbon. Each branch 115 protrudes from the body 113 in a direction along the X axis. The source region 110 is between the two source contacts 140 and 145. The source contact 140 or 145 may include an electrically conductive material, such metal. The source contact 140 or 145 may be coupled to one or more frontside metal layers (e.g., M0, M1, etc.) or one or more backside metal layers (e.g., back M0 (BM0), BM1, etc.). Even though the source region 110 has two source contacts 140 and 145 in FIG. 1A, the source region 110 may have a single contact in other embodiments.

The drain region 120 is also a forked region. The drain region 120 includes a body section (“body”) 123 and three branch sections (“branches”) 125 (individually referred to as “branch section 125” or “branch 125”). The branches 125 are stacked along the Z axis. Even though FIG. 1A shows three branches 125, the drain region 120 may include a different number of branches 125 in other embodiments. A branch 125 may be a fin or nanoribbon. Each branch 125 protrudes from the body 123 in a direction along the X axis. The branches 125 may be connected to the body 123. In some embodiments, the body 123 and the branches 125 may be in an integrated structure. In other embodiments, the body 123 and the branches 125 may be separate structures that are connected. The drain region 120 is between the drain contacts 150 and 155. The drain contact 150 or 155 may include an electrically conductive material, such metal. The drain contact 150 or 155 may be coupled to one or more frontside metal layers (e.g., M0, M1, etc.) or one or more backside metal layers (e.g., back M0 (BM0), BM1, etc.). Even though the drain region 120 has two drain contacts 150 and 155 in FIG. 1A, the drain region 120 may have a single contact in other embodiments.

The channel region 107 is between the source region 110 and the drain region 120. In the embodiments of FIGS. 1A and 1B, the channel region 107 includes three stacked sections, each of which is between a branch 115 and a branch 125 along the Y axis. In other embodiments, the channel region 107 may include a different number of sections. A section in the channel region 107 may be a fin, nanoribbon, or other types of structures.

In some embodiments, two or all of the source region 110, drain region 120, and channel region 107 may be formed using a single fabrication process, e.g., an epitaxial deposition process. In other embodiments, the source region 110, drain region 120, and channel region 107 may be formed separately, e.g., using separate epitaxial deposition processes. In some embodiments, the body and branches in the source region 110 or the drain region 120 may be formed using a single fabrication process. In other embodiments, the body and branches in the source region 110 or the drain region 120 may be formed using separate fabrication processes. In an example, the branches 115, the channel region 107, and the branches 125 may be formed using a single fabrication process, and the bodies 113 and 123 may be formed separately.

The source region 110 and drain region 120 may each include a semiconductor material with dopants. In some embodiments, the source region 110 and drain region 120 have the same semiconductor material, which may be the same as the channel material of the channel region 107. A semiconductor material of the source region 110 or drain region 120 may be a Group IV material, a compound of Group IV materials, a Group III/V material, a compound of Group III/V materials, a Group II/VI material, a compound of Group II/VI materials, or other semiconductor materials. Example Group II materials include zinc (Zn), cadmium (Cd), and so on. Example Group III materials include aluminum (Al), boron (B), indium (In), gallium (Ga), and so on. Example Group IV materials include silicon (Si), germanium (Ge), carbon (C), etc. Example Group V materials include nitrogen (N), phosphorus (P), arsenic (As), antimony (Sb), and so on. Example Group VI materials include sulfur(S), selenium (Se), tellurium (Te), oxygen (O), and so on. A compound of Group IV materials can be a binary compound, such as SiC, SiGe, and so on. A compound of Group III/V materials can be a binary, tertiary, or quaternary compound, such as GaN, InN, and so on. A compound of Group II/VI materials can be a binary, tertiary, or quaternary compounds, such as CdSe, CdS, CdTe, ZnO, ZnSe, ZnS, ZnTe, CdZnTe, CZT, HgCdTe, HgZnTe, and so on.

In some embodiments, the dopants in the source region and the drain region are the same type. In other embodiments, the dopants of the source region and the drain region may be different (e.g., opposite) types. In an example, the source region has N-type dopants and the drain region has P-type dopants. In another example, the source region has P-type dopants and the drain region has N-type dopants. Example N-type dopants include Te, S, As, tin (Sn), Si, Ga, Se, S, In, Al, Cd, chlorine (CI), iodine (I), fluorine (F), and so on. Example P-type dopants include beryllium (Be), Zn, magnesium (Mg), Sn, P, Te, lithium (Li), sodium (Na), Ga, Cd, and so on.

In some embodiments, the source region 110 and drain region 120 may be highly doped, e.g., with dopant concentrations of about 1·10²¹ cm⁻³, in order to advantageously form Ohmic contacts with the respective S/D contacts (also sometimes interchangeably referred to as “S/D electrodes”), although these regions may also have lower dopant concentrations and may form Schottky contacts in some implementations. Irrespective of the exact doping levels, the source region and the drain region may be the regions having dopant concentration higher than in other regions, e.g., higher than a dopant concentration in the channel region 107, and, therefore, may be referred to as “highly doped” (HD) regions.

The channel region 107 may include one or more semiconductor materials with doping concentrations significantly smaller than those of the source region and the drain region. For example, in some embodiments, the channel material of the channel region 107 may be an intrinsic (e.g., undoped) semiconductor material or alloy, not intentionally doped with any electrically active impurity. In alternate embodiments, nominal impurity dopant levels may be present within the channel material, for example to set a threshold voltage Vt, or to provide HALO pocket implants, etc. In such impurity-doped embodiments however, impurity dopant level within the channel material is still significantly lower than the dopant level in the source region and the drain region, for example below 10¹⁵ cm⁻³ or below 10¹³ cm⁻³. Depending on the context, the term “S/D terminal” may refer to a S/D region or a S/D contact or electrode of a transistor.

A channel material may be composed of semiconductor material systems including, for example, N-type or P-type materials systems. In some embodiments, a channel material may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material may include a compound semiconductor with a first sub-lattice of at least one element from Group III of the periodic table (e.g., Al, Ga, In), and a second sub-lattice of at least one element of group V of the periodic table (e.g., P, As, Sb). In some embodiments, the channel material may include a compound semiconductor with a first sub-lattice of at least one element from Group II of the periodic table (e.g., Zn, Cd, Hg), and a second sub-lattice of at least one element of Group IV of the periodic table (e.g., C, Si, Ge, Sn, Pb). In some embodiments, the channel material is an epitaxial semiconductor material deposited using an epitaxial deposition process. The epitaxial semiconductor material may have a polycrystalline structure with a grain size between about 2 nm and 100 nm, including all values and ranges therein.

For some example N-type transistor embodiments (i.e., for the embodiments where the FET 100 is an NMOS transistor), the channel material may advantageously include a III-V material having a high electron mobility, such as, but not limited to InGaAs, InP, InSb, and InAs. For some such embodiments, the channel material may be a ternary III-V alloy, such as InGaAs, GaAsSb, InAsP, or InPSb. For some InxGa1-xAs fin embodiments, In content (x) may be between 0.6 and 0.9, and may advantageously be at least 0.7 (e.g., In0.7Ga0.3As). In some embodiments with highest mobility, the channel material may be an intrinsic III-V material, i.e., a III-V semiconductor material not intentionally doped with any electrically active impurity. In alternate embodiments, a nominal impurity dopant level may be present within the channel material, for example to further fine-tune a threshold voltage Vt, or to provide HALO pocket implants, etc. Even for impurity-doped embodiments however, impurity dopant level within the channel material may be relatively low, for example below 10¹⁵ dopant atoms per cubic centimeter (cm⁻³), and advantageously below 10¹³ cm⁻³. These materials may be amorphous or polycrystalline, e.g., having a crystal grain size between 0.5 nanometers and 100 nanometers.

For some example P-type transistor embodiments (i.e., for the embodiments where the FET is a PMOS transistor), the channel material may advantageously be a Group IV material having a high hole mobility, such as, but not limited to Ge or a Ge-rich SiGe alloy. For some example embodiments, the channel material may have a Ge content between 0.6 and 0.9, and advantageously may be at least 0.7. In some embodiments with highest mobility, the channel material may be intrinsic III-V (or IV for P-type devices) material and not intentionally doped with any electrically active impurity. In alternate embodiments, a nominal impurity dopant level may be present within the channel material, for example to further set a threshold voltage (Vt), or to provide HALO pocket implants, etc. Even for impurity-doped embodiments however, impurity dopant level within the channel portion is relatively low, for example below 10¹⁵ cm⁻³, and advantageously below 10¹³ cm⁻³. These materials may be amorphous or polycrystalline, e.g., having a crystal grain size between 0.5 nanometers and 100 nanometers.

In some embodiments, the channel material may include a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, aluminum zinc oxide, or tungsten oxide. In general, for a thin-film transistor (TFT), the channel material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, molybdenum disulfide, n- or P-type amorphous or polycrystalline silicon, monocrystalline silicon, germanium, indium arsenide, indium gallium arsenide, indium selenide, indium antimonide, zinc antimonide, antimony selenide, silicon germanium, gallium nitride, aluminum gallium nitride, indium phosphite, black phosphorus, zinc sulfide, indium sulfide, gallium sulfide, each of which may possibly be doped with one or more of gallium, indium, aluminum, fluorine, boron, phosphorus, arsenic, nitrogen, tantalum, tungsten, and magnesium, etc. In some embodiments, a thin-film channel material may be deposited at relatively low temperatures, which allows depositing the channel material within the thermal budgets imposed on back-end fabrication to avoid damaging other components, e.g., front-end components such as logic devices.

As noted above, the channel material may include IGZO. IGZO-based devices have several desirable electrical and manufacturing properties. IGZO has high electron mobility compared to other semiconductors, e.g., in the range of 20-50 times than amorphous silicon. Furthermore, amorphous IGZO (a-IGZO) transistors are typically characterized by high band gaps, low-temperature process compatibility, and low fabrication cost relative to other semiconductors.

IGZO can be deposited as a uniform amorphous phase while retaining higher carrier mobility than oxide semiconductors such as zinc oxide. Different formulations of IGZO include different ratios of indium oxide, gallium oxide, and zinc oxide. One particular form of IGZO has the chemical formula InGaO₃ (ZnO)₅. Another example form of IGZO has an indium: gallium: zinc ratio of 1:2:1. In various other examples, IGZO may have a gallium to indium ratio of 1:1, a gallium to indium ratio greater than 1 (e.g., 2:1, 3:1, 4:1, 5:1, 6:1, 7:1, 8:1, 9:1, or 10:1), and/or a gallium to indium ratio less than 1 (e.g., 1:2, 1:3, 1:4, 1:5, 1:6, 1:7, 1:8, 1:9, or 1:10). IGZO can also contain tertiary dopants such as aluminum or nitrogen.

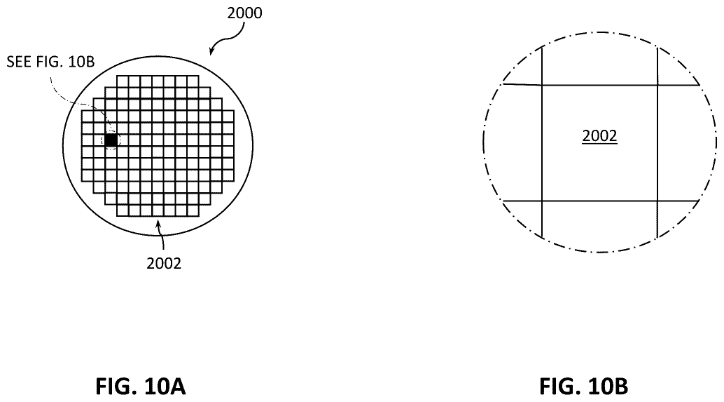

Even though not shown in FIGS. 1A and 1B, the FET 100 may be built based on a support structure, such as a substrate, die, wafer, chip, or other types of structures based on which transistors can be built. The support structure may, e.g., be the wafer 2000 of FIG. 10A, discussed below, and may be, or be included in, a die, e.g., the singulated die 2002 of FIG. 10B, discussed below. In some embodiments, the support structure may be a semiconductor substrate composed of semiconductor material systems including, for example, N-type or P-type materials systems, and, in some embodiments, the channel region 107, described herein, may be a part of the support structure. In some embodiments, the semiconductor substrate may be a crystalline substrate formed using a bulk silicon or a silicon-on-insulator substructure. In other embodiments, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V, group II-VI, or group IV materials. In some embodiments, the substrate may be non-crystalline. In some embodiments, the support structure may be a printed circuit board (PCB) substrate. One or more transistors, such as the FET 100, may be built on the support structure.

Although a few examples of materials from which the support structure may be formed are described here, any material that may serve as a foundation upon which an IC may be built falls within the spirit and scope of the present disclosure. In various embodiments, the support structure may include any such substrate, possibly with some layers and/or devices already formed thereon, not specifically shown in the present figures. As used herein, the term “support” does not necessarily mean that it provides mechanical support for the IC devices/structures (e.g., transistors, capacitors, interconnects, and so on) built thereon. For example, some other structure (e.g., a carrier substrate or a package substrate) may provide such mechanical support and the support structure may provide material “support” in that, e.g., the IC devices/structures described herein are build based on the semiconductor materials of the support structure. However, in some embodiments, the support structure may provide mechanical support.

The gate assembly 130 includes three gate electrodes 133 (individually referred to as “gate electrode 133”), each of which is over a section of the channel region 107. A gate electrode is electrically conductive and may be electrically coupled to a metal layer at the frontside or backside. A gate electrode may include one or more electrical conductors, such as poly, metal, other types of electrical conductors, or some combination thereof. The gate assembly 130 also includes dielectric structures 135 (individually referred to as “dielectric structure 135”), which can separate the gate electrodes 133 from the channel region 107. A dielectric structure 135 includes one or more dielectric materials. At least a portion of a dielectric structure 135 is between a gate electrode 133 and the corresponding section of the channel region 107 along the Z axis. In other embodiments, the number of gate electrodes 133 or dielectric structures 135 may be different.

The gate assembly is between the dielectric layers 160 and 170. The dielectric layer 160 extends to the edge of the branches 115 in a direction along the Y axis, and the dielectric layer 170 extends to the edge of the branches 125 in the opposite direction along the Y axis. The dielectric layer 160 or 170 includes one or more dielectric materials. Example dielectric material includes oxide (e.g., Si based oxides, metal oxides, etc.), high-k dielectric, and so on. Example hysteretic material include ferroelectric materials, antiferroelectric materials, and so on.

As shown in FIGS. 1A and 1B, portions of the dielectric layer 160 is over the body 113, e.g., over portions of the body 113 where no branch protrudes. A portion of the dielectric layer 160 is over the gate assembly 130. portions of the dielectric layer 170 is over the body 123, e.g., over portions of the body 123 where no branch protrudes. A portion of the dielectric layer 170 is over the gate assembly 130. In some embodiments, a portion of the dielectric layer 160 may be over the source contact 140 or 145, and a portion of the dielectric layer 170 may be over the drain contact 150 or 155. The gate assembly 130, the branches 115, and the branches 125 are aligned in the X-Y plane. The bodies 113 and 123 are not aligned with the combined structure including the gate assembly 130, the branches 115, and the branches 125.

The bodies 113 and 123 are at opposite sides of the combined structure in the direction along the X axis. Also, the bodies 113 and 123 are at opposite sides of the combined structure in the direction along the Y axis. In some embodiments, the bodies 113 and 123 are diagonally arranged with respect to the gate assembly 130. As shown in FIG. 1A, the body 113 is at the left back side of the combined structure (or the gate assembly 130) and the body 123 is at the right front side of the combined structure (or the gate assembly 130). Such a design of the FET 100 can reduce the length of the FET along the Y axis, and therefore reduce the CPP in the standard cell. This design can also support connection of the trench contacts (e.g., the source contact 140 or 145 or the drain contact 150 or 155) with frontside or backside metal layers.

The architecture of the FET 100 shown in FIGS. 1A and 1B is an example architecture of FETs with forked semiconductor structure 105s. In other embodiments, FETs with forked semiconductor structure 105s may have different components from the FET 100. For example, the number of branches, gate electrodes 133, or dielectric structures may be different. As another example, the shape of the body, branches, or other components of the FET 100 may be different. Also, the positions of the components may be different.

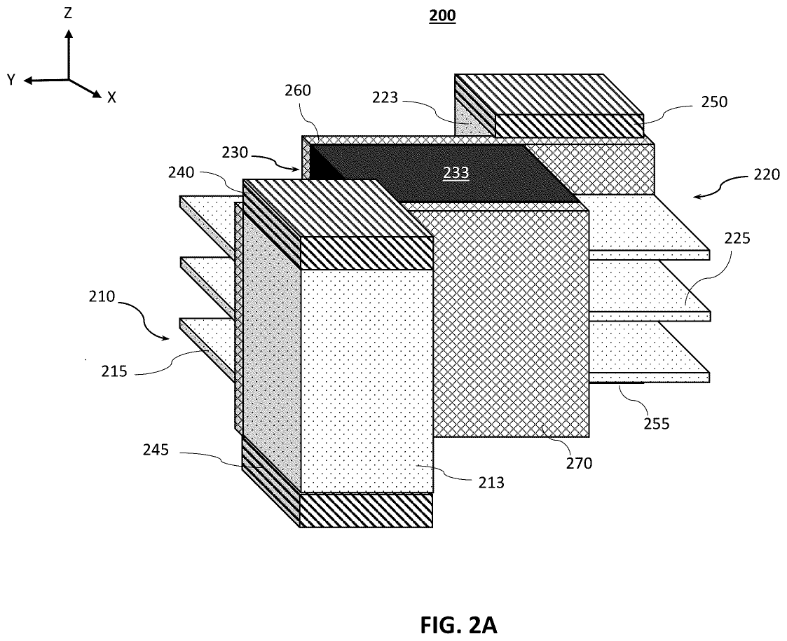

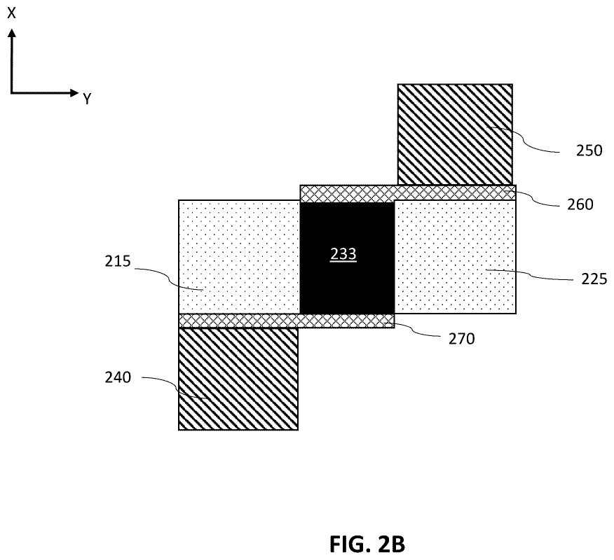

FIGS. 2A and 2B illustrate another example FET 200 with forked semiconductor structures, according to some embodiments of the disclosure. FIG. 2A is a perspective view of the FET 200. FIG. 2B is a top view of the FET 200. The FET 200 may be a P-type transistor (e.g., a PMOS transistor) or an N-type transistor (e.g., an NMOS transistor). The forked semiconductor structure in the FET 200 includes a source region 210 and a drain region 220. The forked semiconductor structure also includes a channel region (invisible in FIGS. 2A and 2B). The FET 200 also includes a gate assembly 230, source contacts 240 and 245, drain contacts 250 and 255, and dielectric layers 260 and 270. In other embodiments, the FET 200 may include different, fewer, or more components.

As shown in FIG. 2A, the source region 210 has a fork shape, i.e., the source region 210 is a forked region. The source region 210 includes a body section (“body”) 213 and three branch sections (“branches”) 215 (individually referred to as “branch section 215” or “branch 215”). The branches 215 are stacked along the Z axis. Even though FIG. 1A shows three branches 215, the source region 210 may include a different number of branches 215 in other embodiments. A branch 215 may be a fin or nanoribbon. Each branch 215 protrudes from the body 213 in a direction along the X axis. The source region 210 is between the two source contacts 240 and 245. The source contact 240 or 245 may include an electrically conductive material, such metal. The source contact 240 or 245 may be coupled to one or more frontside metal layers (e.g., M0, M1, etc.) or one or more backside metal layers (e.g., back M0 (BM0), BM1, etc.). Even though the source region 210 has two source contacts 240 and 245 in FIG. 2A, the source region 210 may have a single contact in other embodiments.

The drain region 220 is also a forked region. The drain region 220 includes a body section (“body”) 223 and three branch sections (“branches”) 225 (individually referred to as “branch section 225” or “branch 225”). The branches 225 are stacked along the Z axis. Even though FIG. 1A shows three branches 225, the drain region 220 may include a different number of branches 225 in other embodiments. A branch 225 may be a fin or nanoribbon. Each branch 225 protrudes from the body 223 in a direction along the X axis. The branches 225 may be connected to the body 223. In some embodiments, the body 223 and the branches 225 may be in an integrated structure. In other embodiments, the body 223 and the branches 225 may be separate structures that are connected. The drain region 220 is between the drain contacts 250 and 255. The drain contact 250 or 255 may include an electrically conductive material, such metal. The drain contact 250 or 255 may be coupled to one or more frontside metal layers (e.g., M0, M1, etc.) or one or more backside metal layers (e.g., back M0 (BM0), BM1, etc.). Even though the drain region 220 has two drain contacts 250 and 255 in FIG. 2A, the drain region 220 may have a single contact in other embodiments.

The channel region is between the source region 210 and the drain region 220. In the embodiments of FIGS. 2A and 2B, the channel region includes three stacked sections, each of which is between a branch 215 and a branch 225 along the Y axis. In other embodiments, the channel region may include a different number of sections. A section in the channel region may be a fin, nanoribbon, or other types of structures.

In some embodiments, the source region 210, drain region 220, and channel region may be formed using a single fabrication process, e.g., an epitaxial deposition process. In other embodiments, the source region 210, drain region 220, and channel region may be formed separately, e.g., using separate epitaxial deposition processes. In some embodiments, the body and branches in the source region 210 or the drain region 220 may be formed using a single fabrication process. In other embodiments, the body and branches in the source region 210 or the drain region 220 may be formed using separate fabrication processes. In an example, the branches 215, the channel region, and the branches 225 may be formed using a single fabrication process, and the bodies 213 and 223 may be formed separately.

The gate assembly 230 includes three gate electrodes 233 (individually referred to as “gate electrode 233”), each of which is over a section of the channel region. A gate electrode is electrically conductive and may be electrically coupled to a metal layer at the frontside or backside. A gate electrode may include one or more electrical conductors, such as poly, metal, other types of electrical conductors, or some combination thereof. The gate assembly 230 also includes dielectric structures 235 (individually referred to as “dielectric structure 235”), which can separate the gate electrodes 233 from the channel region. A dielectric structure 235 includes one or more dielectric materials. At least a portion of a dielectric structure 235 is between a gate electrode 233 and the corresponding section of the channel region along the Z axis. In other embodiments, the number of gate electrodes 233 or dielectric structures 235 may be different.

The gate assembly is between the dielectric layers 260 and 270. The dielectric layer 260 extends to the edge of the branches 215 in a direction along the Y axis, and the dielectric layer 270 extends to the edge of the branches 225 in the opposite direction along the Y axis. The dielectric layer 260 or 270 includes one or more dielectric materials. Example dielectric material includes oxide (e.g., Si based oxides, metal oxides, etc.), high-k dielectric, and so on. Example hysteretic material include ferroelectric materials, antiferroelectric materials, and so on.

As shown in FIGS. 2A and 2B, portions of the dielectric layer 260 is over the body 213, e.g., over portions of the body 213 where no branch protrudes. A portion of the dielectric layer 260 is over the gate assembly 230. portions of the dielectric layer 270 is over the body 223, e.g., over portions of the body 223 where no branch protrudes. A portion of the dielectric layer 270 is over the gate assembly 230. In some embodiments, a portion of the dielectric layer 260 may be over the source contact 240 or 245, and a portion of the dielectric layer 270 may be over the drain contact 250 or 255. The gate assembly 230, the branches 215, and the branches 225 are aligned in the X-Y plane. The bodies 213 and 223 are not aligned with the combined structure including the gate assembly 230, the branches 215, and the branches 225.

The bodies 213 and 223 are at opposite sides of the combined structure in the direction along the X axis. Also, the bodies 213 and 223 are at opposite sides of the combined structure in the direction along the Y axis. As shown in FIG. 2A, the body 213 is at the left front side of the combined structure (or the gate assembly 130), and the body 213 is at the right back side of the combined structure (or the gate assembly 130). In some embodiments, the bodies 213 and 223 are diagonally arranged with respect to the gate assembly 230. Such a design of the FET 200 can reduce the length of the FET along the Y axis, and therefore reduce the CPP in the standard cell. This design can also support connection of the trench contacts (e.g., the source contact 240 or 245 or the drain contact 250 or 255) with frontside or backside metal layers.

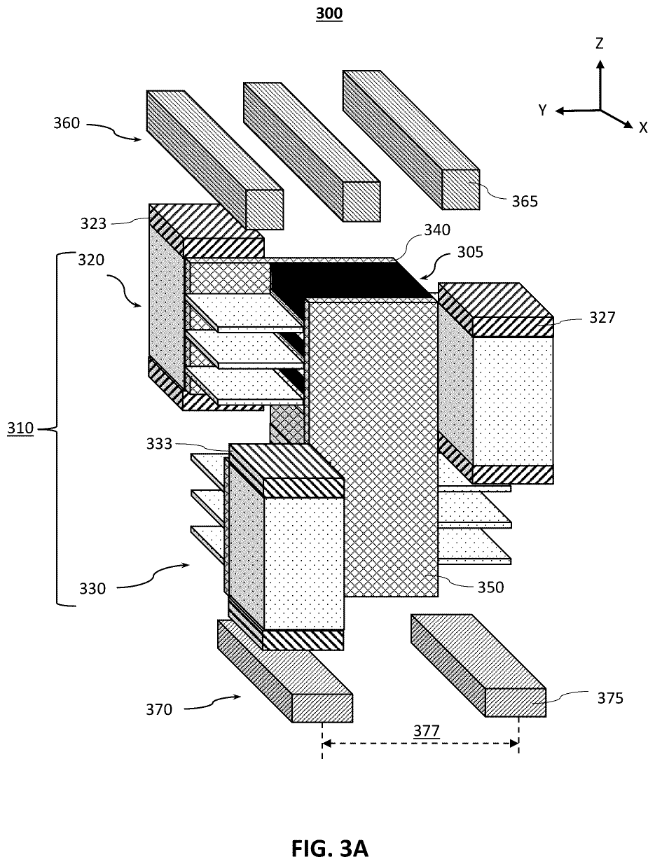

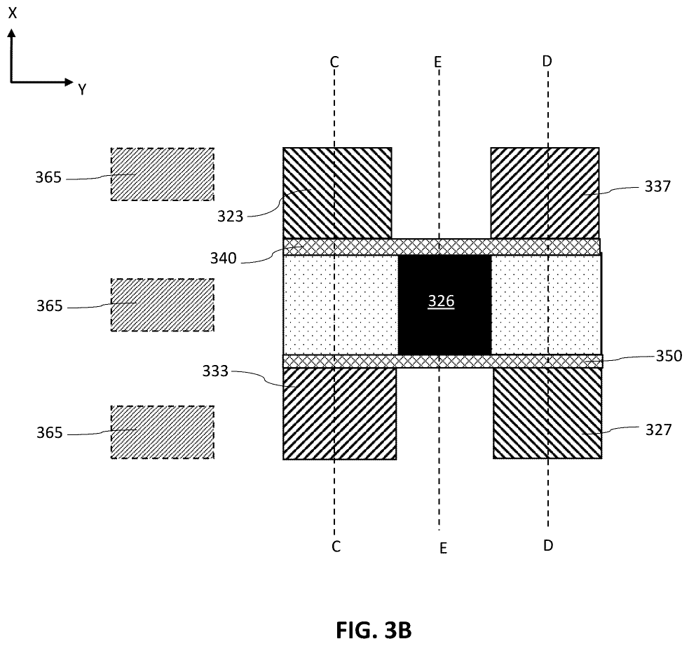

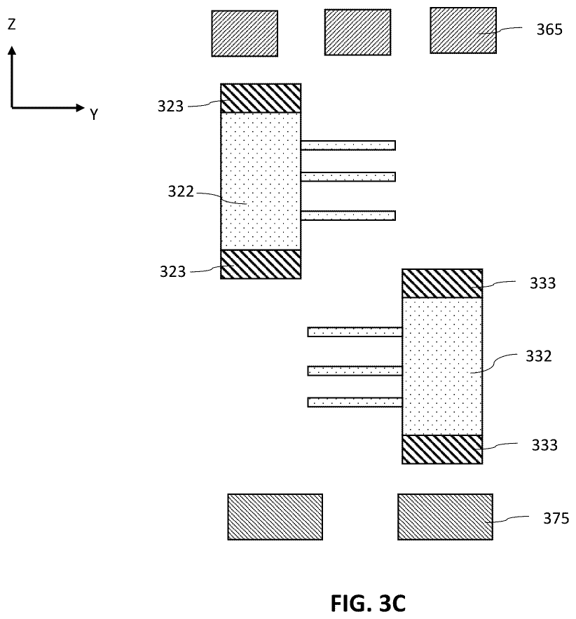

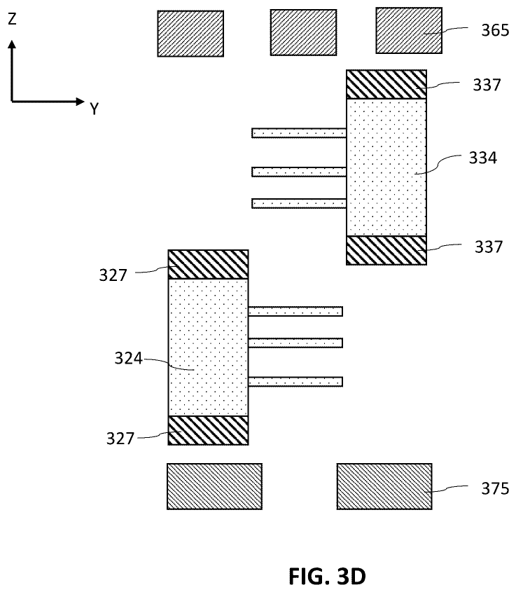

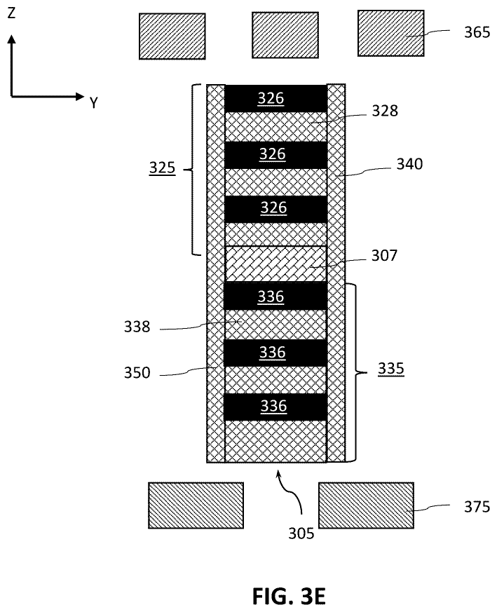

FIGS. 3A-3E illustrate an IC device 300 including a CFET 310 with forked semiconductor structures, according to some embodiments of the disclosure. FIG. 3A is a perspective view of the IC device 300. FIG. 3B is a top view of the IC device 300. FIGS. 3C-3E are cross-sectional views of the IC device 300. FIG. 3C illustrates a cross-section of the IC device 300 in the C-C plane shown in FIG. 3B. FIG. 3D illustrates a cross-section of the IC device 300 in the D-D plane shown in FIG. 3B. FIG. 3E illustrates a cross-section of the IC device 300 in the E-E plane shown in FIG. 3B. As shown in FIGS. 3A-3E, in addition to the CFET 310, the IC device 300 also includes a frontside metal layer 360 and a backside metal layer 370. In other embodiments, the IC device 300 may include different components. For instance, the IC device 300 may include more than one CFET, backside metal layer, or frontside metal layer. The IC device 300 may include a standard cell that includes the CFET 310 and one or more other CFETs. Also, the IC device 300 may include vias for electrically coupling the CFET 310 with the frontside metal layer 360 or the backside metal layer 370.

The CFET 310 includes an FET 320 and another FET 330. The FETs 320 and 330 are stacked along the Z axis. The FET 320 is on top of the FET 330 in the embodiments of FIGS. 3A-3E. In other embodiments, the FET 330 may be on top of the FET 320. In some embodiments, the FET 320 is the opposite type from the FET 330. In an embodiment, the FET 320 is an N-type transistor (e.g., an NMOS transistor), and the FET 330 is a P-type transistor (e.g., a PMOS transistor). The source region 322 and drain region 324 may be N-doped, and the source region 332 and drain region 334 may be P-doped. In another embodiment, the FET 320 is a P-type transistor (e.g., a PMOS transistor), and the FET 330 is an N-type transistor (e.g., an NMOS transistor). The source region 322 and drain region 324 may be P-doped, and the source region 332 and drain region 334 may be N-doped. By stacking the FET 320 over the FET 330, the height of a standard cell including the CFET 310 can be increased. In other embodiments, more FETs may be stacked along the Z axis in the CFET 310.

The FET 320 includes a source region 322 and a drain region 324, each of which has a forked structure with a body and branches extending from a surface of the body. The body of the source region 322 is between two source contacts 323. The body of the drain region 324 is between two drain contacts 337. The FET 330 includes a source region 332 and a drain region 334, each of which has a forked structure. The body of the source region 332 is between two source contacts 333. The body of the drain region 334 is between two drain contacts 337. The FET 320 may be an embodiment of the FET 100 in FIGS. 1A and 1B. The FET 330 may be an embodiment of the FET 200 in FIGS. 2A and 2B.

The FET 320 also includes a gate assembly 325 including a plurality of gate electrodes 326 and dielectric structures 328. The FET 330 also includes a gate assembly 335 including a plurality of gate electrodes 336 and dielectric structures 338. The gate electrodes 326 and the dielectric structures 328 may form an alternating pattern. Also, the gate electrodes 336 and the dielectric structures 338 may form an alternating pattern. The gate assembly 325 of the FET 320 is over the gate assembly 335 of the FET 330. In some embodiments, the gate assembly 325 may be aligned with the gate assembly 335 along the Z axis. The gate assembly 325 and gate assembly 335 may constitute a single gate assembly 305 of the CFET 310, which is between a dielectric layer 340 and another dielectric layer 350 along the X axis. In some embodiments, an electrical insulator 307 may separate the gate assembly 325 from the gate assembly 335. The electrical insulator 307 may be a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The frontside metal layer 360 is on top of the CFET 310. The frontside metal layer 360 includes structures 365 (individually referred to as “structure 365”). The backside metal layer 370 is under the CFET 310. The backside metal layer 370 includes structures 375 (individually referred to as “structure 375”). Each structure 365 or 375 is electrically conductive. A structure 365 or 375 may be a metal track. Even though not shown in FIGS. 3A-3E, one or more structures 365 or 375 may be electrically coupled to the CFET 310. For instance, a structure 365 or 375 may be electrically coupled to the gate assembly 325 or 335, e.g., a gate electrode 329 in the gate assembly 325. A structure 365 or 367 may be electrically coupled to a source contact 323 or drain contact 327 in the FET 320 or a source contact 333 or drain contact 337 in the FET 330. The frontside metal layer 360 may be M0, i.e., the metal layer that is closest to the CFET 310 at the frontside of the IC device 300. The backside metal layer 370 may be BM0, i.e., the metal layer that is closest to the CFET310 at the backside of the IC device 300. In some embodiments, a pitch 377 of the backside metal layer 370 may be the same or substantially similar as the height of the standard cell. The pitch 377 may be the distance from a center of a structure 375 to a center of the other structure 375 along the Y axis. The height of the standard cell may be defined based on the number of the structures 365 in the frontside metal layer 360.

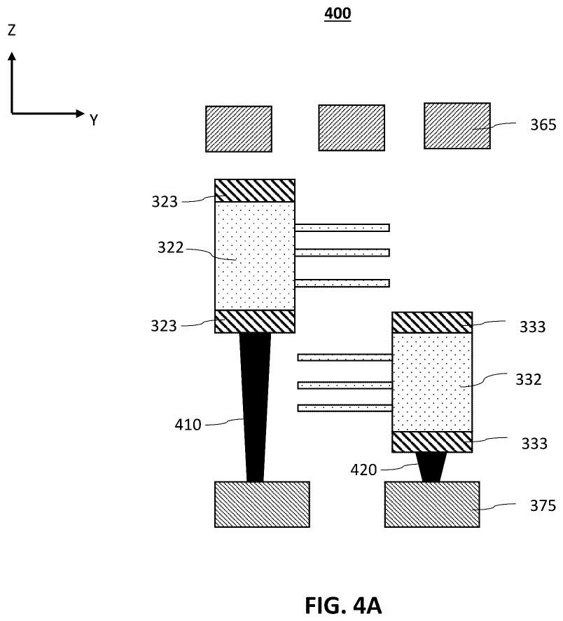

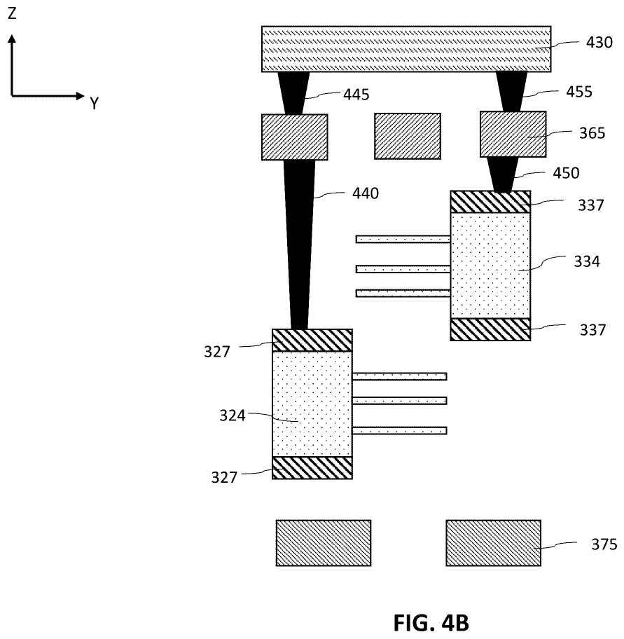

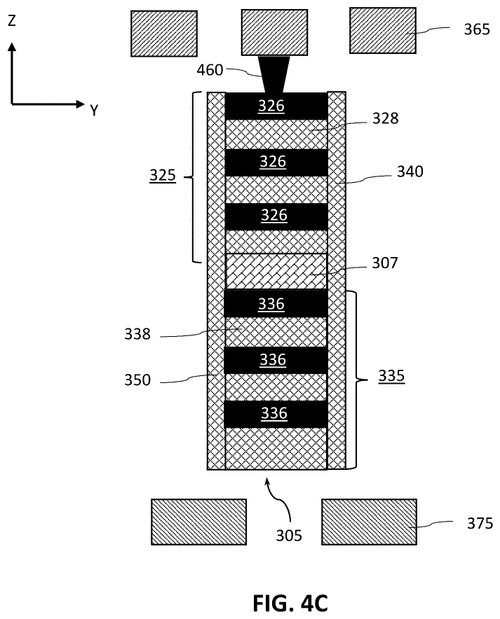

FIGS. 4A-4C illustrate an example standard cell 400 including the CFET 310 and having pin access in M1, according to some embodiments of the disclosure. FIGS. 4A-4C are cross-sectional views of the standard cell 400. In FIG. 4A, a source contact 323 of the FET 320 in the CFET 310 is electrically coupled to a structure 375 in the backside metal layer 370 through a via 410. The via 410 has one end connected to the source contact 323 and the other end connected to the structure 375. Also, a source contact 333 of the FET 330 in the CFET 310 is electrically coupled to another structure 375 in the backside metal layer 370 through a via 420. The via 420 has one end connected to the source contact 323 and the other end connected to the structure 375. The via 410 or 420 includes an electrical conductor, such as metal, etc. In some embodiments, a structure 375 may function as a power plane or ground plane. For instance, the two structures 375 may be voltage source supply (VSS) and voltage common collector (VCC), respectively.

FIG. 4B shows another metal layer 430, which is above the frontside metal layer 360. In some embodiments, the metal layer 430 is M1. In FIG. 4B, a drain contact 327 of the FET 320 in the CFET 310 is electrically coupled to a structure 365 in the frontside metal layer 360 through a via 440. Also, a drain contact 337 of the FET 330 in the CFET 310 is electrically coupled to another structure 365 in the frontside metal layer 360 through a via 450, respectively. Moreover, the two structures 365 are electrically coupled to the metal layer 430 through vias 445 and 455, respectively. In some embodiments, the electrical connection between the metal layer 430, the structures 365, and the drain contacts 327 and 337 (e.g., the electrical connection supported by the vias 440, 450, 445, and 455) can facilitate signal transmission. The metal layer 430 can provide pin access, e.g., for receiving input signal or sending out output signal of the standard cell 400.

In FIG. 4C, a structure 365 in the frontside metal layer 360 is electrically coupled to a gate electrode 326 through a via 460. The electrical connection may facilitate power delivery to the gate electrode 326. Even though not shown in FIG. 4C, the structure 365 may also be electrically coupled to one or more other gate electrodes 326 or one or more gate electrodes 336.

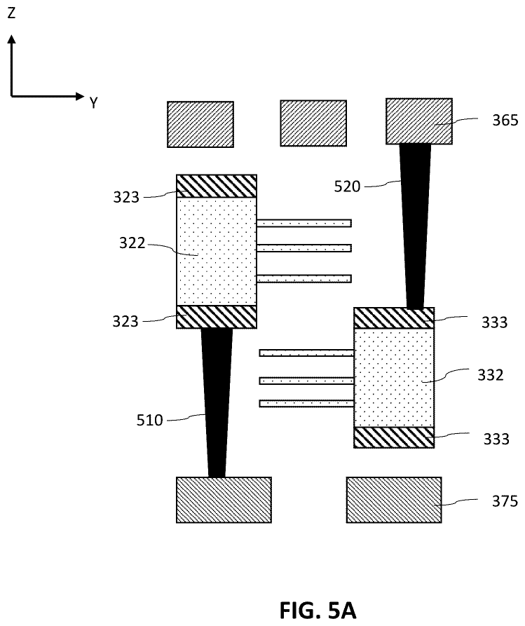

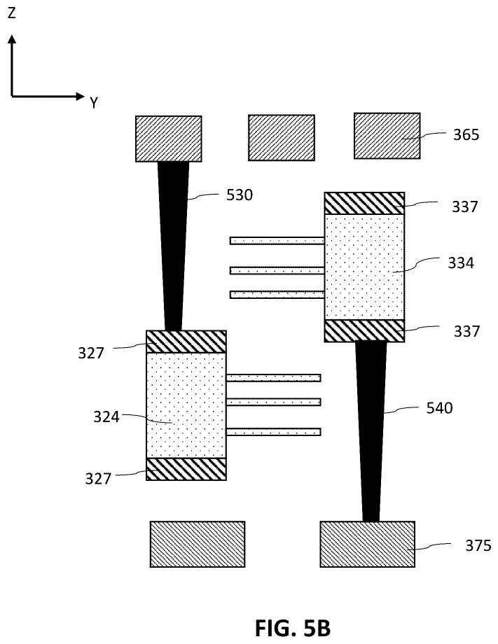

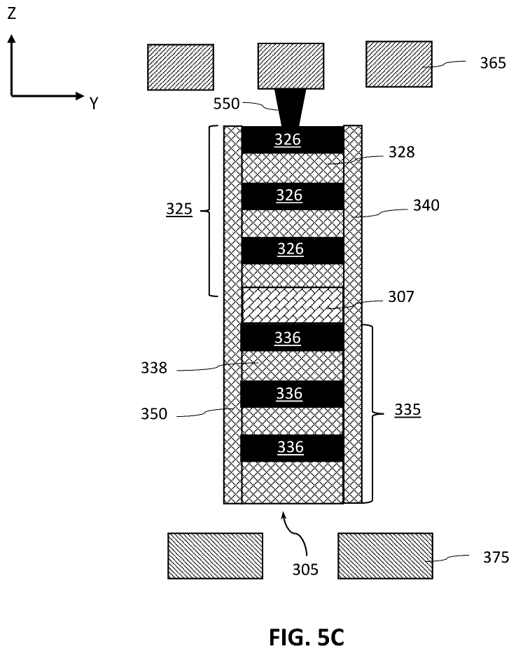

FIGS. 5A-5D illustrate another example standard cell 500 including the CFET 310 and having pin access in M1, according to some embodiments of the disclosure, according to some embodiments of the disclosure. FIGS. 5A-5C are cross-sectional views of the standard cell 500. In FIG. 5A, a source contact 323 of the FET 320 in the CFET 310 is electrically coupled to a structure 375 in the backside metal layer 370 through a via 510. The source contact 323 is below the source region 322. The via 510 has one end connected to the source contact 323 and the other end connected to the structure 375. Also, a source contact 333 of the FET 330 in the CFET 310 is electrically coupled to a structure 365 in the frontside metal layer 360 through a via 520. The source contact 333 is above the source region 332. The via 520 has one end connected to the source contact 323 and the other end connected to the structure 375. The via 510 or 520 includes an electrical conductor, such as metal, etc. The electrical connection through the via 520 may facilitate transmission of signal. In some embodiments, a structure 375 may function as a power plane or ground plane. For instance, the two structures 375 may be VSS and VCC, respectively.

In FIG. 5B, a drain contact 327 of the FET 320 in the CFET 310 is electrically coupled to a structure 365 in the frontside metal layer 360 through a via 540. The drain contact 327 is above the drain region 324. Also, a drain contact 337 of the FET 330 in the CFET 310 is electrically coupled to another structure 365 in the frontside metal layer 360 through a via 540. The drain contact 337 is below the drain region 334. The electrical connection through the via 530 may facilitate transmission of signal. Even though not shown in FIG. 5B, the standard cell 500 may include a metal layer (e.g., M1) above the frontside metal layer 360, the metal layer may be electrically coupled to the via 520 or 530 for signal transmission.

In FIG. 5C, a structure 365 in the frontside metal layer 360 is electrically coupled to a gate electrode 326 through a via 550. The electrical connection may facilitate power delivery to the gate electrode 326. Even though not shown in FIG. 5C, the structure 365 may also be electrically coupled to one or more other gate electrodes 326 or one or more gate electrodes 336.

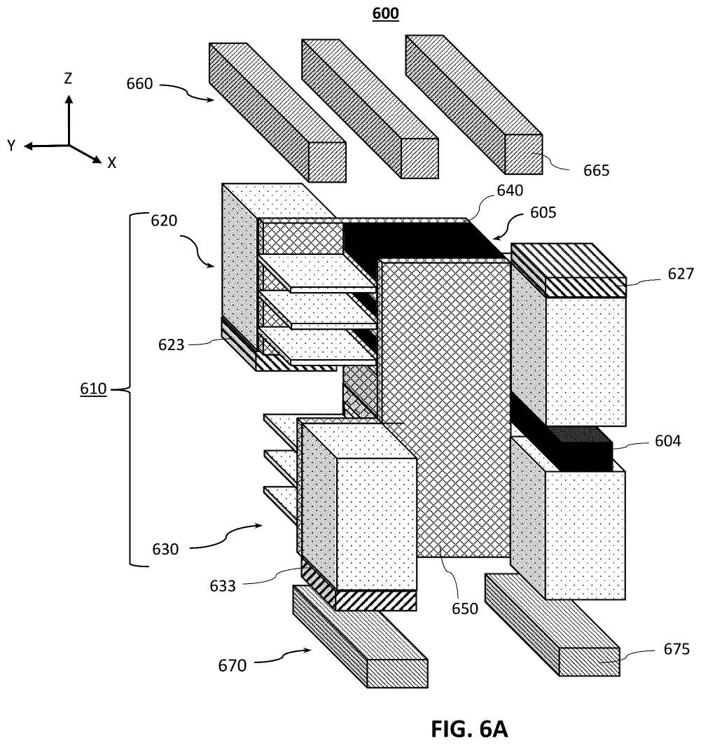

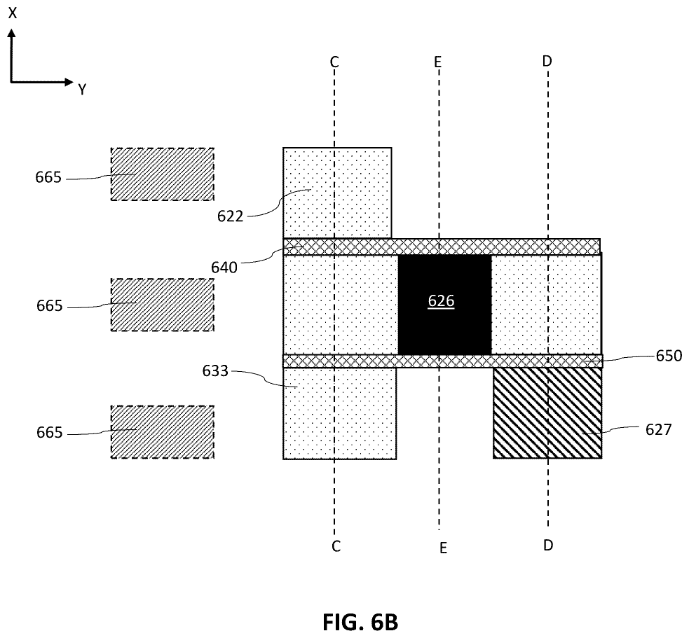

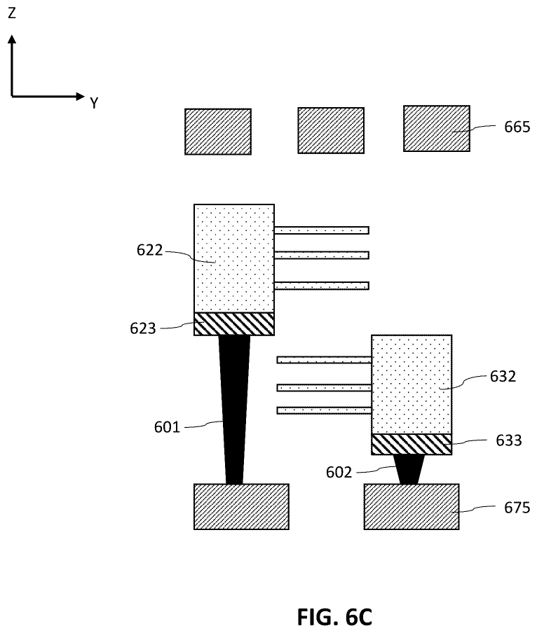

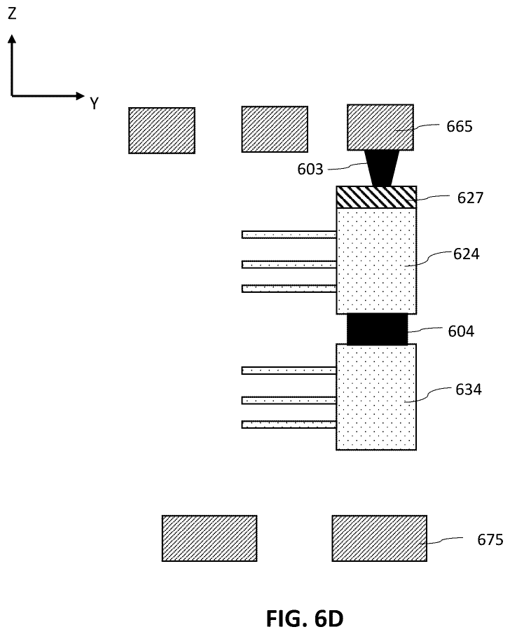

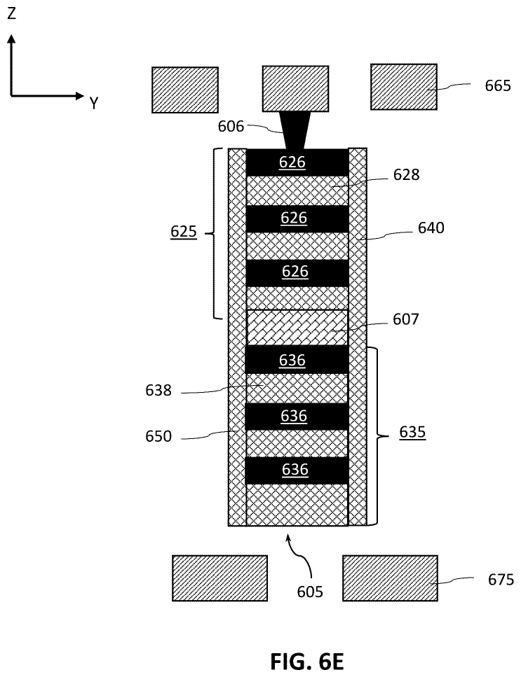

FIGS. 6A-6E illustrate an example standard cell 600 including a hybrid CFET 610 and having pin access in M0, according to some embodiments of the disclosure. FIG. 6A is a perspective view of the standard cell 600. FIG. 6B is a top view of the standard cell 600. FIGS. 6C-6E are cross-sectional views of the standard cell 600. FIG. 6C illustrates a cross-section of the standard cell 600 in the C-C plane shown in FIG. 6B. FIG. 6D illustrates a cross-section of the standard cell 600 in the D-D plane shown in FIG. 6B. FIG. 6E illustrates a cross-section of the standard cell 600 in the E-E plane shown in FIG. 6B.

As shown in FIGS. 6A-6E, in addition to the hybrid CFET 610, the standard cell 600 also includes a frontside metal layer 660 and a backside metal layer 670. In other embodiments, the standard cell 600 may include different components. For instance, the standard cell 600 may include more than one CFET, backside metal layer, or frontside metal layer. The standard cell 600 may include a standard cell that includes the hybrid CFET 610 and one or more other CFETs. Also, the standard cell 600 may include vias for electrically coupling the hybrid CFET 610 with the frontside metal layer 660 or the backside metal layer 670. FIGS. 6C-6E shows electrical connections of the hybrid CFET 610 with the frontside metal layer 660 or the backside metal layer 670. For the purpose of simplicity and illustrations, the vias are not shown in FIG. 6A or FIG. 6B.

The hybrid CFET 610 includes an FET 620 and another FET 630. The FET 620 includes a source region 622 and a drain region 624, each of which has a forked structure with a body and branches extending from a surface of the body. The body of the source region 622 is between two source contacts 623. The body of the drain region 624 is between two drain contacts 637. The FET 630 includes a source region 632 and a drain region 634, each of which has a forked structure. The body of the source region 632 is between two source contacts 633. The body of the drain region 634 is between two drain contacts 637.

The FET 620 also includes a gate assembly 625 including a plurality of gate electrodes 626 and dielectric structures 628. The FET 630 also includes a gate assembly 635 including a plurality of gate electrodes 636 and dielectric structures 638. The gate electrodes 626 and the dielectric structures 628 may form an alternating pattern. Also, the gate electrodes 636 and the dielectric structures 638 may form an alternating pattern. The gate assembly 625 of the FET 620 is over the gate assembly 635 of the FET 630. In some embodiments, the gate assembly 625 may be aligned with the gate assembly 635 along the Z axis. The gate assembly 625 and gate assembly 635 may constitute a single gate assembly 605 of the hybrid CFET 610, which is between a dielectric layer 640 and a dielectric layer 650 along the X axis. In some embodiments, an electrical insulator 607 may separate the gate assembly 625 from the gate assembly 635. The electrical insulator 607 may be a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The FETs 620 and 630 are stacked along the Z axis. The FET 620 is on top of the FET 630 in the embodiments of FIGS. 6A-6E. In other embodiments, the FET 630 may be on top of the FET 620. The FET 620 has a different architecture from the FET 630. As shown in FIG. 6A, the body of the source region 622 is on the left back side of the gate assembly 605, and the body of the drain region 624 of the FET 620 is on the right front side of the gate assembly 605. The two bodies are diagonally arranged with respect to the gate assembly 605. However, the body of the source region 632 and the body of the drain region 634 of the FET 620 are both on the front side of the gate assembly 605. The FET 620 may be an embodiment of the FET 100 in FIGS. 1A and 1B. The FET 630 may be a E₂-FET. In some embodiments, the FET 620 is the opposite type from the FET 630. In an embodiment, the FET 620 is an N-type transistor (e.g., an NMOS transistor), and the FET 630 is a P-type transistor (e.g., a PMOS transistor). The source region 622 and drain region 624 may be N-doped, and the source region 632 and drain region 634 may be P-doped. In another embodiment, the FET 620 is a P-type transistor (e.g., a PMOS transistor), and the FET 630 is an N-type transistor (e.g., an NMOS transistor).

The frontside metal layer 660 is on top of the hybrid CFET 610. The frontside metal layer 660 includes structures 665 (individually referred to as “structure 665”). The backside metal layer 670 is under the hybrid CFET 610. The backside metal layer 670 includes structures 675 (individually referred to as “structure 675”). Each structure 665 or 675 is electrically conductive. Even though not shown in FIGS. 6A-3E, one or more structures 665 or 675 may be electrically coupled to the hybrid CFET 610. For instance, a structure 665 or 675 may be electrically coupled to the gate assembly 625 or 635, e.g., a gate electrode 629 in the gate assembly 625. A structure 665 or 667 may be electrically coupled to a source contact 623 or drain contact 627 in the FET 620 or a source contact 633 or drain contact 637 in the FET 630. The frontside metal layer 660 may be M0, i.e., the metal layer that is closest to the hybrid CFET 610 at the frontside of the standard cell 600. The backside metal layer 670 may be BM0, i.e., the metal layer that is closest to the CFET310 at the backside of the standard cell 600. In some embodiments, a pitch of the backside metal layer 670 may be the same or substantially similar as the height of the standard cell 600. The pitch may be the distance from a center of a structure 675 to a center of the other structure 675 along the Y axis.

In FIG. 6C, a source contact 623 of the FET 620 in the hybrid CFET 610 is electrically coupled to a structure 675 in the backside metal layer 670 through a via 601. The via 601 has one end connected to the source contact 623 and the other end connected to the structure 675. The source contact 623 is below the source region 622. Also, a source contact 633 of the FET 630 in the hybrid CFET 610 is electrically coupled to another structure 675 in the backside metal layer 670 through a via 602. The source contact 633 is below the source region 632. The via 602 has one end connected to the source contact 623 and the other end connected to the structure 675. The via 601 or 602 includes an electrical conductor, such as metal, etc. In some embodiments, a structure 675 may function as a power plane or ground plane. For instance, the two structures 675 may be VSS and VCC, respectively.

In FIG. 6D, a drain contact 627 of the FET 620 in the hybrid CFET 610 is electrically coupled to a structure 665 in the frontside metal layer 660 through a via 603. The drain contact 637 is above the drain region 624. The electrical connection using the via 603 may support signal transmission. For instance, a pin may be implemented in the frontside metal layer 660 for receiving input signal or sending out output signal. An electrically conductive structure 604 is between the drain region 624 and the drain region 634, particularly between the bodies of the drain regions 624 and 634.

In FIG. 6E, a structure 665 in the frontside metal layer 660 is electrically coupled to a gate electrode 626 through a via 606. The electrical connection may facilitate power delivery to the gate electrode 626. Even though not shown in FIG. 6E, the structure 665 may also be electrically coupled to one or more other gate electrodes 626 or one or more gate electrodes 636.

FIGS. 7A-7D illustrate another example standard cell 700 including a hybrid CFET 710 and having pin access in M0, according to some embodiments of the disclosure. FIG. 7A is a perspective view of the standard cell 700. FIG. 7B is a top view of the standard cell 700. FIGS. 7C-6E are cross-sectional views of the standard cell 700. FIG. 7C illustrates a cross-section of the standard cell 700 in the C-C plane shown in FIG. 7B. FIG. 7D illustrates a cross-section of the standard cell 700 in the D-D plane shown in FIG. 7B. FIG. 7E illustrates a cross-section of the standard cell 700 in the E-E plane shown in FIG. 7B.

As shown in FIGS. 7A-6E, in addition to the hybrid CFET 710, the standard cell 700 also includes a frontside metal layer 760 and a backside metal layer 770. In other embodiments, the standard cell 700 may include different components. For instance, the standard cell 700 may include more than one CFET, backside metal layer, or frontside metal layer. The standard cell 700 may include a standard cell that includes the hybrid CFET 710 and one or more other CFETs. Also, the standard cell 700 may include vias for electrically coupling the hybrid CFET 710 with the frontside metal layer 760 or backside metal layer 770. FIGS. 7C-7E shows electrical connections of the hybrid CFET 710 with the frontside metal layer 760 or backside metal layer 770 using vias. For the purpose of simplicity and illustrations, the vias are not shown in FIG. 7A or FIG. 7B.

The hybrid CFET 710 includes an FET 720 and another FET 730. The FET 720 includes a source region 722 and a drain region 724, each of which has a forked structure with a body and branches extending from a surface of the body. The body of the source region 722 is between two source contacts 723. The body of the drain region 724 is between two drain contacts 737. The FET 730 includes a source region 732 and a drain region 734, each of which has a forked structure. The body of the source region 732 is between two source contacts 733. The body of the drain region 734 is between two drain contacts 737.

The FET 720 also includes a gate assembly 725 including a plurality of gate electrodes 726 and dielectric structures 728. The FET 730 also includes a gate assembly 735 including a plurality of gate electrodes 736 and dielectric structures 738. The gate electrodes 726 and the dielectric structures 728 may form an alternating pattern. Also, the gate electrodes 736 and the dielectric structures 738 may form an alternating pattern. The gate assembly 725 of the FET 720 is over the gate assembly 735 of the FET 730. In some embodiments, the gate assembly 725 may be aligned with the gate assembly 735 along the Z axis. The gate assembly 725 and gate assembly 735 may constitute a single gate assembly 705 of the hybrid CFET 710, which is between a dielectric layer 740 and a dielectric layer 750 along the X axis. In some embodiments, an electrical insulator 707 may separate the gate assembly 725 from the gate assembly 735. The electrical insulator 707 may be a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The FETs 720 and 730 are stacked along the Z axis. The FET 720 is on top of the FET 730 in the embodiments of FIGS. 7A-7E. In other embodiments, the FET 730 may be on top of the FET 720. The FET 720 has a different architecture from the FET 730. As shown in FIG. 7A, the body of the source region 722 is on the left back side of the gate assembly 705, and the body of the drain region 724 of the FET 720 is on the right front side of the gate assembly 705. The two bodies are diagonally arranged with respect to the gate assembly 705. However, the body of the source region 732 and the body of the drain region 734 of the FET 720 are both on the front side of the gate assembly 705. The FET 720 may be an embodiment of the FET 100 in FIGS. 1A and 1B. The FET 730 may be a E₂-FET. In some embodiments, the FET 720 is the opposite type from the FET 730. In an embodiment, the FET 720 is an N-type transistor (e.g., an NMOS transistor), and the FET 730 is a P-type transistor (e.g., a PMOS transistor). The source region 722 and drain region 724 may be N-doped, and the source region 732 and drain region 734 may be P-doped. In another embodiment, the FET 720 is a P-type transistor (e.g., a PMOS transistor), and the FET 730 is an N-type transistor (e.g., an NMOS transistor).

The frontside metal layer 760 is on top of the hybrid CFET 710. The frontside metal layer 760 includes structures 765 (individually referred to as “structure 765”). The backside metal layer 770 is under the hybrid CFET 710. The backside metal layer 770 includes structures 775 (individually referred to as “structure 775”). Each structure 765 or 775 is electrically conductive. Even though not shown in FIGS. 7A-3E, one or more structures 765 or 775 may be electrically coupled to the hybrid CFET 710. For instance, a structure 765 or 775 may be electrically coupled to the gate assembly 725 or 735, e.g., a gate electrode 729 in the gate assembly 725. A structure 765 or 767 may be electrically coupled to a source contact 723 or drain contact 727 in the FET 720 or a source contact 733 or drain contact 737 in the FET 730. The frontside metal layer 760 may be M0, i.e., the metal layer that is closest to the hybrid CFET 710 at the frontside of the standard cell 700. The backside metal layer 770 may be BM0, i.e., the metal layer that is closest to the CFET310 at the backside of the standard cell 700. In some embodiments, a pitch of the backside metal layer 770 may be the same or substantially similar as the height of the standard cell 700. The pitch may be the distance from a center of a structure 775 to a center of the other structure 775 along the Y axis.

In FIG. 7C, a source contact 723 of the FET 720 in the hybrid CFET 710 is electrically coupled to a structure 775 in the backside metal layer 770 through a via 701. The via 701 has one end connected to the source contact 723 and the other end connected to the structure 775. The source contact 723 is below the source region 722. Also, a source contact 733 of the FET 730 in the hybrid CFET 710 is electrically coupled to another structure 775 in the backside metal layer 770 through a via 702. The source contact 733 is below the source region 732. The via 702 has one end connected to the source contact 723 and the other end connected to the structure 775. The via 701 or 702 includes an electrical conductor, such as metal, etc. In some embodiments, a structure 775 may function as a power plane or ground plane. For instance, the two structures 775 may be VSS and VCC, respectively.

In FIG. 7D, a drain contact 727 of the FET 720 in the hybrid CFET 710 is electrically coupled to a structure 765 in the frontside metal layer 760 through a via 703. The drain contact 737 is above the drain region 724. The electrical connection using the via 703 may support signal transmission. For instance, a pin may be implemented in the frontside metal layer 760 for receiving input signal or sending out output signal. Also, a drain contact 737 of the FET 730 in the hybrid CFET 710 is electrically coupled to a structure 775 in the backside metal layer 770 through a via 704. The drain contact 737 is below the drain region 724. The structure 775 may function as a power plane or ground plane. For instance, the structure 775 may be VCC in embodiments where the FET 730 is a PMOS transistor. The structure 775 may be VSS VCC in embodiments where the FET 730 is a NMOS transistor.

In FIG. 7E, a structure 765 in the frontside metal layer 760 is electrically coupled to a gate electrode 726 through a via 706. The electrical connection may facilitate power delivery to the gate electrode 726. Even though not shown in FIG. 7E, the structure 765 may also be electrically coupled to one or more other gate electrodes 726 or one or more gate electrodes 736.

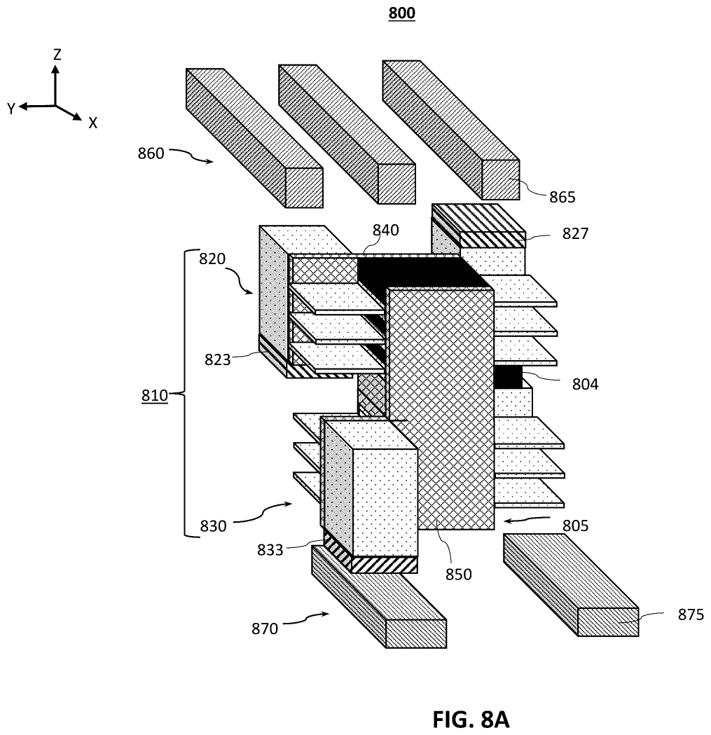

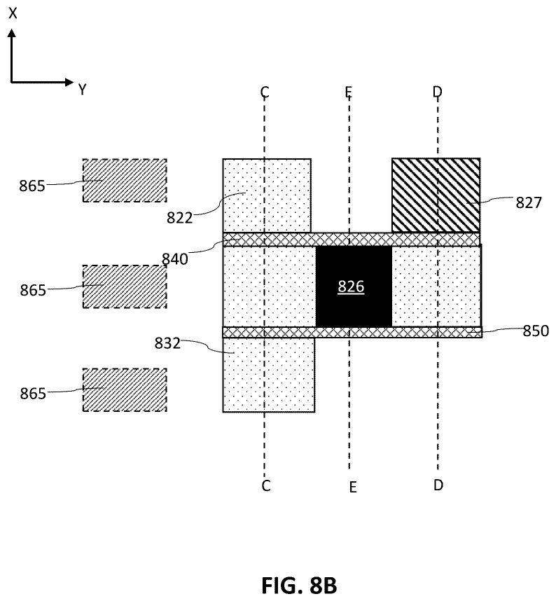

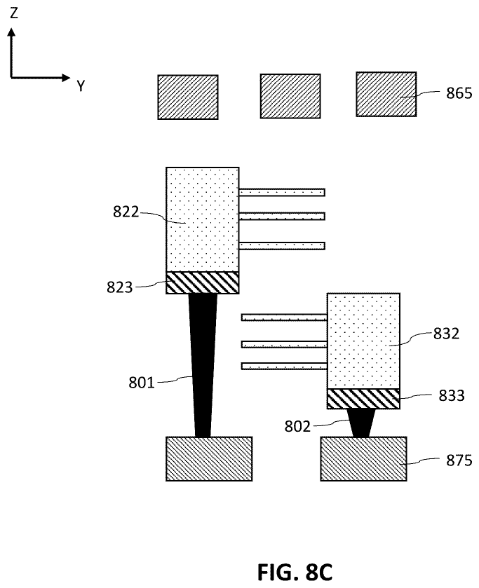

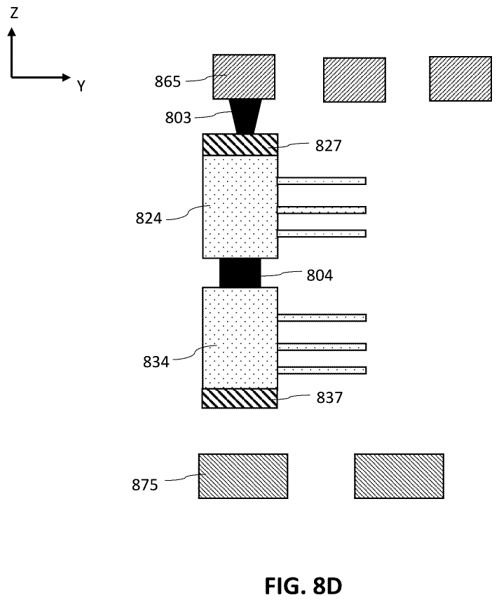

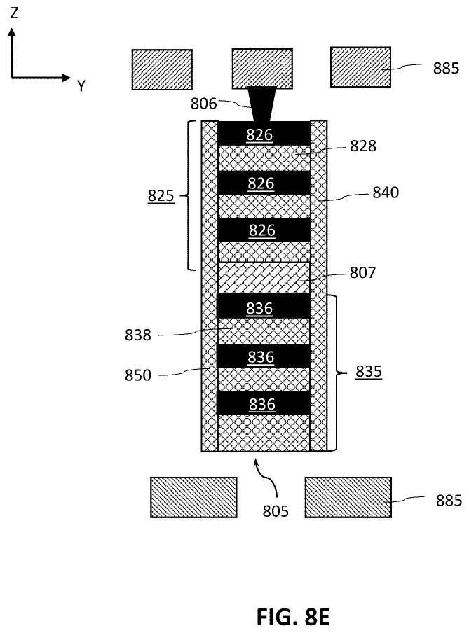

FIGS. 8A-8D illustrate yet another example standard cell 800 including a hybrid CFET 810 and having pin access in M0, according to some embodiments of the disclosure. FIG. 8A is a perspective view of the standard cell 800. FIG. 8B is a top view of the standard cell 800. FIGS. 8C-6E are cross-sectional views of the standard cell 800. FIG. 8C illustrates a cross-section of the standard cell 800 in the C-C plane shown in FIG. 8B. FIG. 8D illustrates a cross-section of the standard cell 800 in the D-D plane shown in FIG. 8B. FIG. 8E illustrates a cross-section of the standard cell 800 in the E-E plane shown in FIG. 8B.

As shown in FIGS. 8A-6E, in addition to the hybrid CFET 810, the standard cell 800 also includes a frontside metal layer 830 and a backside metal layer 840. In other embodiments, the standard cell 800 may include different components. For instance, the standard cell 800 may include more than one CFET, backside metal layer, or frontside metal layer. The standard cell 800 may include a standard cell that includes the hybrid CFET 810 and one or more other CFETs. Also, the standard cell 800 may include vias for electrically coupling the hybrid CFET 810 with the frontside metal layer 830 or backside metal layer 840. FIGS. 8C-6E shows electrical connections of the hybrid CFET 810 with the frontside metal layer 830 or backside metal layer 840 using vias. For the purpose of simplicity and illustrations, the vias are not shown in FIG. 8A or FIG. 8B.

The hybrid CFET 810 includes an FET 820 and another FET 830. The FET 820 includes a source region 822 and a drain region 824, each of which has a forked structure with a body and branches extending from a surface of the body. The body of the source region 822 is between two source contacts 823. The body of the drain region 824 is between two drain contacts 837. The FET 830 includes a source region 832 and a drain region 834, each of which has a forked structure. The body of the source region 832 is between two source contacts 833. The body of the drain region 834 is between two drain contacts 837.

The FET 820 also includes a gate assembly 825 including a plurality of gate electrodes 826 and dielectric structures 828. The FET 830 also includes a gate assembly 835 including a plurality of gate electrodes 836 and dielectric structures 838. The gate electrodes 826 and the dielectric structures 828 may form an alternating pattern. Also, the gate electrodes 836 and the dielectric structures 838 may form an alternating pattern. The gate assembly 825 of the FET 820 is over the gate assembly 835 of the FET 830. In some embodiments, the gate assembly 825 may be aligned with the gate assembly 835 along the Z axis. The gate assembly 825 and gate assembly 835 may constitute a single gate assembly 805 of the hybrid CFET 810, which is between a dielectric layer 840 and a dielectric layer 850 along the X axis. In some embodiments, an electrical insulator 807 may separate the gate assembly 825 from the gate assembly 835. The electrical insulator 807 may be a dielectric material, hysteretic material, and so on. Example dielectric material includes oxide (e.g., Si based oxides, metal oxides, etc.), high-k dielectric, and so on. Example hysteretic material include ferroelectric materials, antiferroelectric materials, etc.

The FETs 820 and 830 are stacked along the Z axis. The FET 820 is on top of the FET 830 in the embodiments of FIGS. 8A-8E. In other embodiments, the FET 830 may be on top of the FET 820. The FET 820 has a different architecture from the FET 830. As shown in FIG. 8A, the body of the source region 822 is on the left back side of the gate assembly 805, and the body of the drain region 824 of the FET 820 is on the right back side of the gate assembly 805. The two bodies are not diagonally arranged with respect to the gate assembly 805. However, the body of the source region 832 is on the left front side of the gate assembly 805, and the body of the drain region 834 of the FET 820 is on the right back side of the gate assembly 805. The two bodies are diagonally arranged with respect to the gate assembly 805. The FET 820 may be a E₂-FET. The FET 830 may be an embodiment of the FET 200 in FIGS. 2A and 2B. In some embodiments, the FET 820 is the opposite type from the FET 830. In an embodiment, the FET 820 is an N-type transistor (e.g., an NMOS transistor), and the FET 830 is a P-type transistor (e.g., a PMOS transistor). The source region 822 and drain region 824 may be N-doped, and the source region 832 and drain region 834 may be P-doped. In another embodiment, the FET 820 is a P-type transistor (e.g., a PMOS transistor), and the FET 830 is an N-type transistor (e.g., an NMOS transistor).

The frontside metal layer 860 is on top of the hybrid CFET 810. The frontside metal layer 860 includes structures 865 (individually referred to as “structure 865”). The backside metal layer 870 is under the hybrid CFET 810. The backside metal layer 870 includes structures 875 (individually referred to as “structure 875”). Each structure 865 or 875 is electrically conductive. Even though not shown in FIGS. 8A-3E, one or more structures 865 or 875 may be electrically coupled to the hybrid CFET 810. For instance, a structure 865 or 875 may be electrically coupled to the gate assembly 825 or 835, e.g., a gate electrode 829 in the gate assembly 825. A structure 865 or 867 may be electrically coupled to a source contact 823 or drain contact 827 in the FET 820 or a source contact 833 or drain contact 837 in the FET 830. The frontside metal layer 860 may be M0, i.e., the metal layer that is closest to the hybrid CFET 810 at the frontside of the standard cell 800. The backside metal layer 870 may be BM0, i.e., the metal layer that is closest to the CFET310 at the backside of the standard cell 800. In some embodiments, a pitch of the backside metal layer 870 may be the same or substantially similar as the height of the standard cell 800. The pitch may be the distance from a center of a structure 875 to a center of the other structure 875 along the Y axis.

In FIG. 8C, a source contact 823 of the FET 820 in the hybrid CFET 810 is electrically coupled to a structure 875 in the backside metal layer 870 through a via 801. The via 801 has one end connected to the source contact 823 and the other end connected to the structure 875. The source contact 823 is below the source region 822. Also, a source contact 833 of the FET 830 in the hybrid CFET 810 is electrically coupled to another structure 875 in the backside metal layer 870 through a via 802. The source contact 833 is below the source region 832. The via 802 has one end connected to the source contact 823 and the other end connected to the structure 875. The via 801 or 802 includes an electrical conductor, such as metal, etc. In some embodiments, a structure 875 may function as a power plane or ground plane. For instance, the two structures 875 may be VSS and VCC, respectively.

In FIG. 8D, a drain contact 827 of the FET 820 in the hybrid CFET 810 is electrically coupled to a structure 865 in the frontside metal layer 860 through a via 803. The drain contact 837 is above the drain region 824. The electrical connection using the via 803 may support signal transmission. For instance, a pin may be implemented in the frontside metal layer 860 for receiving input signal or sending out output signal. An electrically conductive structure 804 is between the drain region 824 and the drain region 834, particularly between the bodies of the drain regions 824 and 834.

In FIG. 8E, a structure 865 in the frontside metal layer 860 is electrically coupled to a gate electrode 826 through a via 806. The electrical connection may facilitate power delivery to the gate electrode 826. Even though not shown in FIG. 8E, the structure 865 may also be electrically coupled to one or more other gate electrodes 826 or one or more gate electrodes 836.

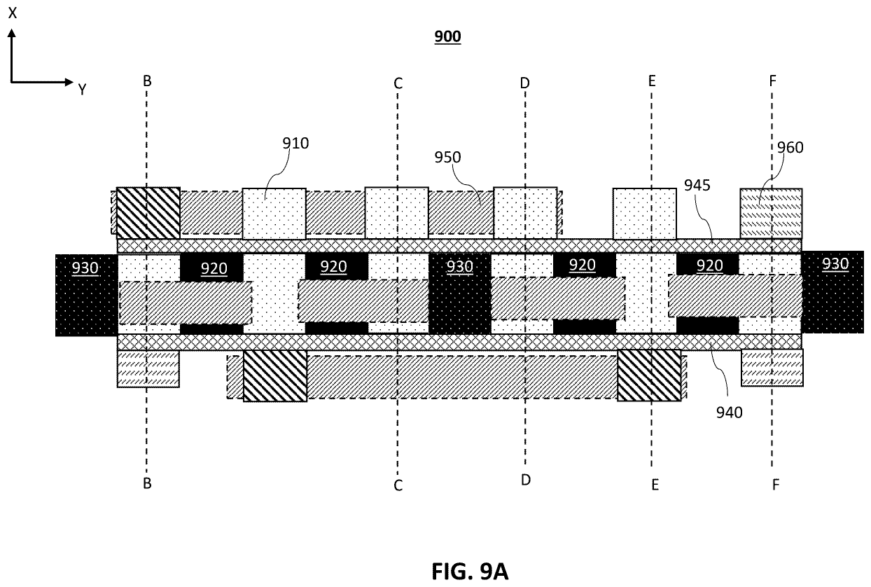

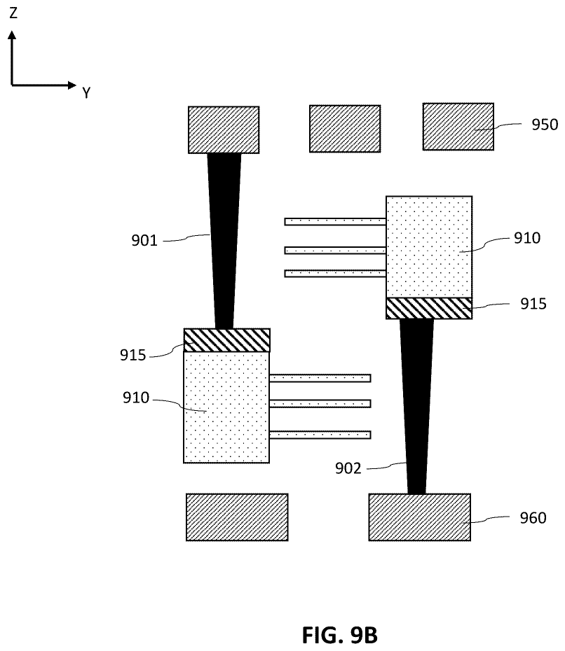

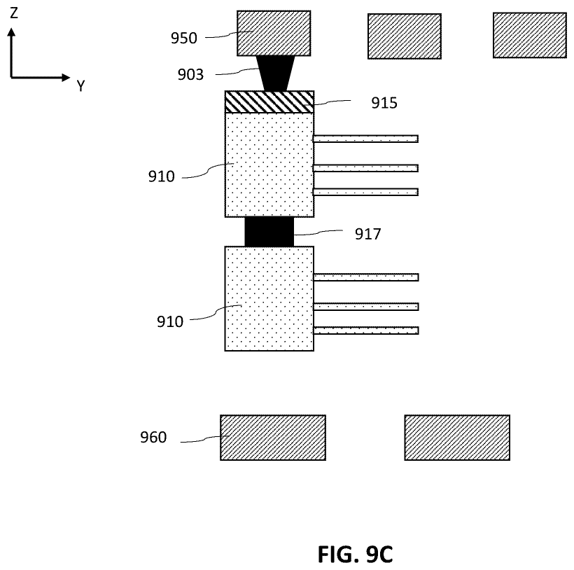

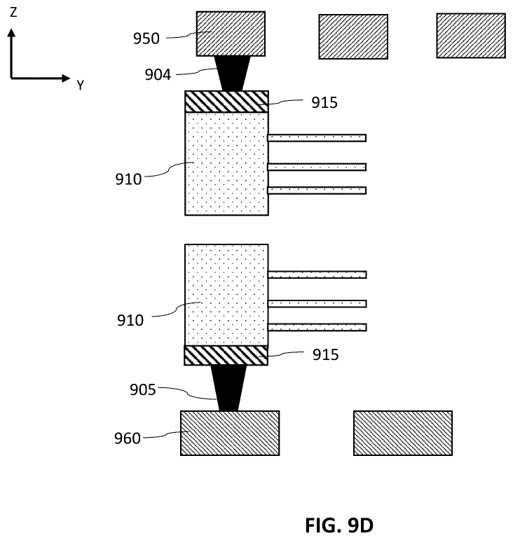

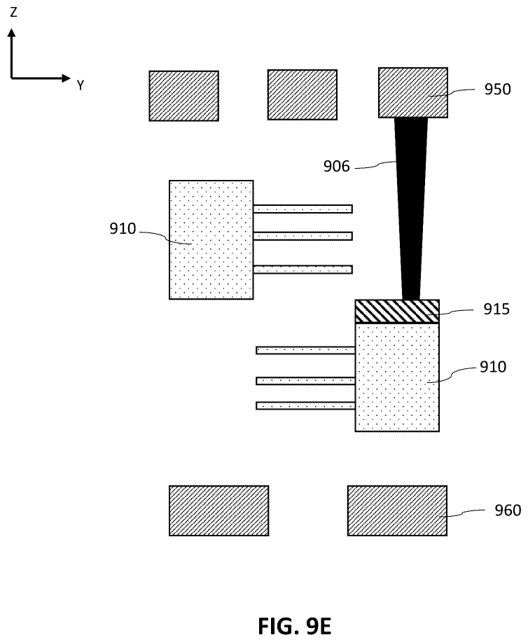

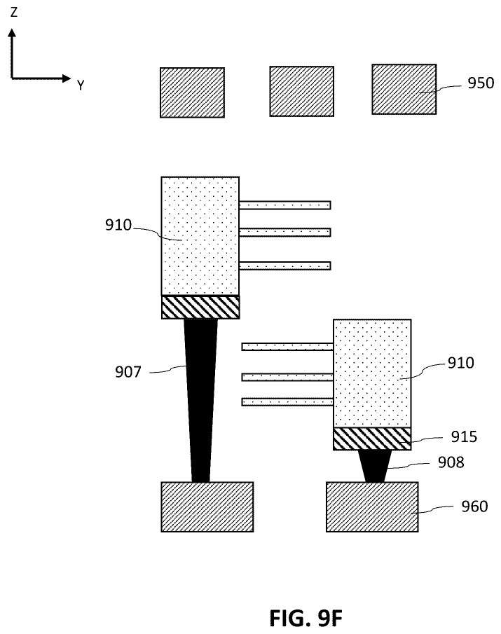

FIGS. 9A-9F illustrate an IC device 900 including a plurality of CFETs with forked semiconductor structures, according to some embodiments of the disclosure. FIG. 9A is a top view of the IC device 900. FIGS. 9B-9F are cross-sectional views of the IC device 900. FIG. 9B is a cross-section of the IC device 900 in the B-B plane shown in FIG. 9A. FIG. 9C is a cross-section of the IC device 900 in the C-C plane shown in FIG. 9A. FIG. 9D is a cross-section of the IC device 900 in the D-D plane shown in FIG. 9A. FIG. 9E is a cross-section of the IC device 900 in the E-E plane shown in FIG. 9A. FIG. 9F is a cross-section of the IC device 900 in the F-F plane shown in FIG. 9A. A CFET in the IC device 900 may be an embodiment of the CFET 310 in FIG. 3, the hybrid CFET 610 in FIG. 6, the hybrid CFET 710 in FIG. 7, or the hybrid CFET 810 in FIG. 8.

The IC device 900 includes a plurality of semiconductor regions 910 (individually referred to as “semiconductor region 910”), a plurality of trench contacts 915 (individually referred to as “trench contact 915”), an electrically conductive structure 917, a plurality of gates 920, a plurality of dummy gates 930, a dielectric layer 940, another dielectric layer 945, a frontside metal layer including a plurality of structures 950, a backside metal layer including a plurality of structures 960, and eight vias 901-908. For the purpose of simplicity and illustrations, the trench contacts 915, electrically conductive structure 917, and vias 901-908 are not shown in FIG. 9A but are shown in FIGS. 9B-9F. In other embodiments, the IC device 900 may include different, fewer, or more components.

A semiconductor region 910 may be a source region or drain region in a CFET. A trench contact 915 may be a source contact or a drain contact. A gate 920 may be a gate in a CFET. In some embodiments, a gate 920 may include one or more gate electrodes. A dummy gate 930 may include one or more dummy gate electrodes. A dummy gate electrode may be electrically conductive but not electrically coupled to other components in the IC device 900 or other devices. A gate 920 or a dummy gate 930 may include an electrical conductor, such as metal, poly, and so on. The vias 901-907 are electrically conductive.

In FIG. 9B, a trench contact 915 on top of a semiconductor region 910 is electrically coupled to a structure 950 through a via 901. The via 901 has one end connected to the trench contact 915 and the other end connected to the structure 950. In some embodiments, the connection using the via 901 may facilitate signal transmission. For instance, the frontside metal layer (e.g., M0) may provide pin access through which input signals may be received by one or more CFETs or output signals may be sent out from one or more CFETs. Also, a trench contact 915 under a semiconductor region 910 is electrically coupled to a structure 960 through a via 902. The via 902 has one end connected to the trench contact 915 and the other end connected to the structure 960. In some embodiments, the structure 960 may function as a power plane or ground plane. For instance, the structure 960 may be VSS or VCC, respectively.

In FIG. 9C, a trench contact 915 above a semiconductor region 910 is electrically coupled to a structure 955 in the frontside metal layer 860 through a via 903. The electrical connection using the via 803 may support signal transmission. An electrically conductive structure 917 is between the semiconductor region 910 another semiconductor region 910 and is connected to the two semiconductor regions 910.

In FIG. 9D, a trench contact 915 on top of a semiconductor region 910 is electrically coupled to a structure 950 through a via 904. In some embodiments, the connection using the via 904 may facilitate signal transmission. Also, a trench contact 915 under a semiconductor region 910 is electrically coupled to a structure 960 through a via 905. In some embodiments, the structure 960 may function as a power plane or ground plane. For instance, the structure 960 may be VSS or VCC, respectively.

In FIG. 9E, a trench contact 915 on top of a semiconductor region 910 is electrically coupled to a structure 950 through a via 906. In some embodiments, the connection using the via 906 may facilitate signal transmission. The other semiconductor region 910 in FIG. 9E is not coupled to other components shown in FIG. 9E in the cross-section of the IC device 900 in the E-E plane.

In FIG. 9F, a trench contact 915 under a semiconductor region 910 is electrically coupled to a structure 960 through a via 907. Also, a trench contact 915 under another semiconductor region 910 is electrically coupled to a structure 960 through a via 908. In some embodiments, either of the two structures 960 in FIG. 9F may function as a power plane or ground plane. For instance, the two structures 960 may be VSS and VCC, respectively.

FIGS. 10A-10B are top views of a wafer 2000 and dies 2002 that may include CFET with forked semiconductor structure, according to some embodiments of the disclosure. In some embodiments, the dies 2002 may be included in an IC package, according to some embodiments of the disclosure. For example, any of the dies 2002 may serve as any of the dies 2256 in an IC package 2200 shown in FIG. 11. The wafer 2000 may be composed of semiconductor material and may include one or more dies 2002 having IC devices formed on a surface of the wafer 2000. Each of the dies 2002 may be a repeating unit of a semiconductor product that includes any suitable IC (e.g., ICs including CFET with forked semiconductor structure as described herein). After the fabrication of the semiconductor product is complete (e.g., after manufacture of CFET with forked semiconductor structure as described herein), the wafer 2000 may undergo a singulation process in which each of the dies 2002 is separated from one another to provide discrete “chips” of the semiconductor product. In particular, devices that include CFET with forked semiconductor structure as disclosed herein may take the form of the wafer 2000 (e.g., not singulated) or the form of the die 2002 (e.g., singulated). The die 2002 may include one or more diodes, one or more transistors as well as, optionally, supporting circuitry to route electrical signals to the III-N diodes with N-doped wells and capping layers and III-N transistors, as well as any other IC components. In some embodiments, the wafer 2000 or the die 2002 may implement an electrostatic discharge (ESD) protection device, a radio frequency front-end device, a memory device (e.g., a static random-access memory (SRAM) device), a logic device (e.g., an AND, OR, NAND, or NOR gate), or any other suitable circuit element. Multiple ones of these devices may be combined on a single die 2002.

FIG. 11 is a side, cross-sectional view of an example IC package 2200 that may include one or more IC devices having CFET with forked semiconductor structure, according to some embodiments of the disclosure. In some embodiments, the IC package 2200 may be a system-in-package (SiP).

As shown in FIG. 11, the IC package 2200 may include a package substrate 2252. The package substrate 2252 may be formed of a dielectric material (e.g., a ceramic, a glass, a combination of organic and inorganic materials, a buildup film, an epoxy film having filler particles therein, etc., and may have embedded portions having different materials), and may have conductive pathways extending through the dielectric material between the face 2272 and the face 2274, or between different locations on the face 2272, and/or between different locations on the face 2274.

The package substrate 2252 may include conductive contacts 2263 that are coupled to conductive pathways 2262 through the package substrate 2252, allowing circuitry within the dies 2256 and/or the interposer 2257 to electrically couple to various ones of the conductive contacts 2264 (or to other devices included in the package substrate 2252, not shown).

The IC package 2200 may include an interposer 2257 coupled to the package substrate 2252 via conductive contacts 2261 of the interposer 2257, first-level interconnects 2265, and the conductive contacts 2263 of the package substrate 2252. The first-level interconnects 2265 illustrated in FIG. 11 are solder bumps, but any suitable first-level interconnects 2265 may be used. In some embodiments, no interposer 2257 may be included in the IC package 2200; instead, the dies 2256 may be coupled directly to the conductive contacts 2263 at the face 2272 by first-level interconnects 2265.

The IC package 2200 may include one or more dies 2256 coupled to the interposer 2257 via conductive contacts 2254 of the dies 2256, first-level interconnects 2258, and conductive contacts 2260 of the interposer 2257. The conductive contacts 2260 may be coupled to conductive pathways (not shown) through the interposer 2257, allowing circuitry within the dies 2256 to electrically couple to various ones of the conductive contacts 2261 (or to other devices included in the interposer 2257, not shown). The first-level interconnects 2258 illustrated in FIG. 11 are solder bumps, but any suitable first-level interconnects 2258 may be used. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

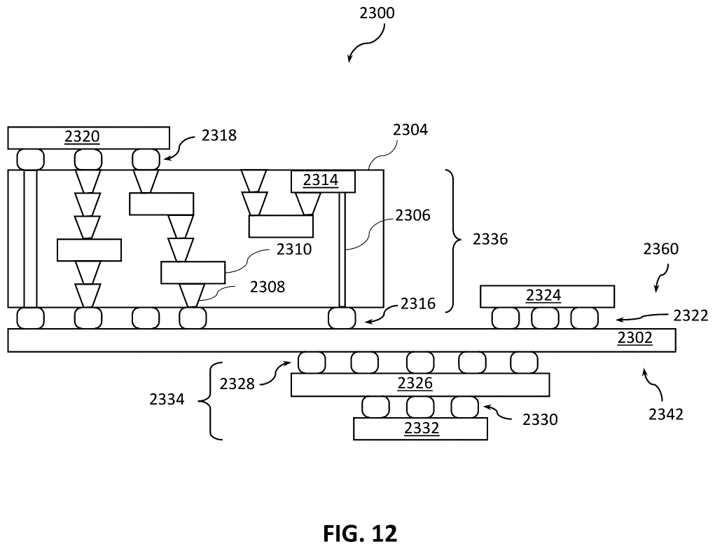

In some embodiments, an underfill material 2266 may be disposed between the package substrate 2252 and the interposer 2257 around the first-level interconnects 2265, and a mold compound 2268 may be disposed around the dies 2256 and the interposer 2257 and in contact with the package substrate 2252. In some embodiments, the underfill material 2266 may be the same as the mold compound 2268. Example materials that may be used for the underfill material 2266 and the mold compound 2268 are epoxy mold materials, as suitable. Second-level interconnects 2270 may be coupled to the conductive contacts 2264. The second-level interconnects 2270 illustrated in FIG. 11 are solder balls (e.g., for a ball grid array arrangement), but any suitable second-level interconnects 2270 may be used (e.g., pins in a pin grid array arrangement or lands in a land grid array arrangement). The second-level interconnects 2270 may be used to couple the IC package 2200 to another component, such as a circuit board (e.g., a motherboard), an interposer, or another IC package, as known in the art and as discussed below with reference to FIG. 12.

The dies 2256 may take the form of any of the embodiments of the die 2002 discussed herein and may include any of the embodiments of an IC device having CFET with forked semiconductor structure. In embodiments in which the IC package 2200 includes multiple dies 2256, the IC package 2200 may be referred to as a multi-chip package. Importantly, even in such embodiments of an MCP implementation of the IC package 2200, CFET with forked semiconductor structure may be provided in a single chip, in accordance with any of the embodiments described herein. The dies 2256 may include circuitry to perform any desired functionality. For example, one or more of the dies 2256 may be ESD protection dies, including CFET with forked semiconductor structure as described herein, one or more of the dies 2256 may be logic dies (e.g., silicon-based dies), one or more of the dies 2256 may be memory dies (e.g., high bandwidth memory), etc. In some embodiments, any of the dies 2256 may include CFET with forked semiconductor structure, e.g., as discussed above; in some embodiments, at least some of the dies 2256 may not include any III-N diodes with N-doped wells and capping layers.

The IC package 2200 illustrated in FIG. 11 may be a flip chip package, although other package architectures may be used. For example, the IC package 2200 may be a ball grid array (BGA) package, such as an embedded wafer-level ball grid array (eWLB) package. In another example, the IC package 2200 may be a wafer-level chip scale package (WLCSP) or a panel fan-out (FO) package. Although two dies 2256 are illustrated in the IC package 2200 of FIG. 11, an IC package 2200 may include any desired number of the dies 2256. An IC package 2200 may include additional passive components, such as surface-mount resistors, capacitors, and inductors disposed on the first face 2272 or the second face 2274 of the package substrate 2252, or on either face of the interposer 2257. More generally, an IC package 2200 may include any other active or passive components known in the art.

FIG. 12 is a cross-sectional side view of an IC device assembly 2300 that may include components having one or more IC devices implementing CFET with forked semiconductor structure, according to some embodiments of the disclosure. The IC device assembly 2300 includes a number of components disposed on a circuit board 2302 (which may be, e.g., a motherboard). The IC device assembly 2300 includes components disposed on a first face 2340 of the circuit board 2302 and an opposing second face 2342 of the circuit board 2302; generally, components may be disposed on one or both faces 2340 and 2342. In particular, any suitable ones of the components of the IC device assembly 2300 may include any of the IC devices implementing CFET with forked semiconductor structure in accordance with any of the embodiments disclosed herein; e.g., any of the IC packages discussed below with reference to the IC device assembly 2300 may take the form of any of the embodiments of the IC package 2200 discussed above with reference to FIG. 11 (e.g., may include CFET with forked semiconductor structure in/on a die 2256).

In some embodiments, the circuit board 2302 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2302. In other embodiments, the circuit board 2302 may be a non-PCB substrate.

The IC device assembly 2300 illustrated in FIG. 12 includes a package-on-interposer structure 2336 coupled to the first face 2340 of the circuit board 2302 by coupling components 2316. The coupling components 2316 may electrically and mechanically couple the package-on-interposer structure 2336 to the circuit board 2302, and may include solder balls (e.g., as shown in FIG. 12), male and female portions of a socket, an adhesive, an underfill material, and/or any other suitable electrical and/or mechanical coupling structure.

The package-on-interposer structure 2336 may include an IC package 2320 coupled to an interposer 2304 by coupling components 2318. The coupling components 2318 may take any suitable form for the application, such as the forms discussed above with reference to the coupling components 2316. The IC package 2320 may be or include, for example, a die (the die 2002 of FIG. 10B), an IC device (e.g., the IC device of FIGS. 1-2), or any other suitable component. In particular, the IC package 2320 may include CFET with forked semiconductor structure as described herein. Although a single IC package 2320 is shown in FIG. 12, multiple IC packages may be coupled to the interposer 2304; indeed, additional interposers may be coupled to the interposer 2304. The interposer 2304 may provide an intervening substrate used to bridge the circuit board 2302 and the IC package 2320. Generally, the interposer 2304 may spread a connection to a wider pitch or reroute a connection to a different connection. For example, the interposer 2304 may couple the IC package 2320 (e.g., a die) to a BGA of the coupling components 2316 for coupling to the circuit board 2302. In the embodiment illustrated in FIG. 12, the IC package 2320 and the circuit board 2302 are attached to opposing sides of the interposer 2304; in other embodiments, the IC package 2320 and the circuit board 2302 may be attached to a same side of the interposer 2304. In some embodiments, three or more components may be interconnected by way of the interposer 2304.

The interposer 2304 may be formed of an epoxy resin, a fiberglass-reinforced epoxy resin, a ceramic material, or a polymer material such as polyimide. In some implementations, the interposer 2304 may be formed of alternate rigid or flexible materials that may include the same materials described above for use in a semiconductor substrate, such as silicon, germanium, and other group III-V and group IV materials. The interposer 2304 may include metal interconnects 2308 and vias 2310, including but not limited to TSVs 2306. The interposer 2304 may further include embedded devices 2314, including both passive and active devices. Such devices may include, but are not limited to, capacitors, decoupling capacitors, resistors, inductors, fuses, diodes, transformers, sensors, ESD protection devices, and memory devices. More complex devices such as further RF (radio frequency) devices, power amplifiers, power management devices, antennas, arrays, sensors, and microelectromechanical systems (MEMS) devices may also be formed on the interposer 2304. In some embodiments, the IC devices implementing CFET with forked semiconductor structure as described herein may also be implemented in/on the interposer 2304. The package-on-interposer structure 2336 may take the form of any of the package-on-interposer structures known in the art.

The IC device assembly 2300 may include an IC package 2324 coupled to the first face 2340 of the circuit board 2302 by coupling components 2322. The coupling components 2322 may take the form of any of the embodiments discussed above with reference to the coupling components 2316, and the IC package 2324 may take the form of any of the embodiments discussed above with reference to the IC package 2320.

The IC device assembly 2300 illustrated in FIG. 12 includes a package-on-package structure 2334 coupled to the second face 2342 of the circuit board 2302 by coupling components 2328. The package-on-package structure 2334 may include an IC package 2326 and an IC package 2332 coupled together by coupling components 2330 such that the IC package 2326 is disposed between the circuit board 2302 and the IC package 2332. The coupling components 2328 and 2330 may take the form of any of the embodiments of the coupling components 2316 discussed above, and the IC packages 2326 and 2332 may take the form of any of the embodiments of the IC package 2320 discussed above. The package-on-package structure 2334 may be configured in accordance with any of the package-on-package structures known in the art.

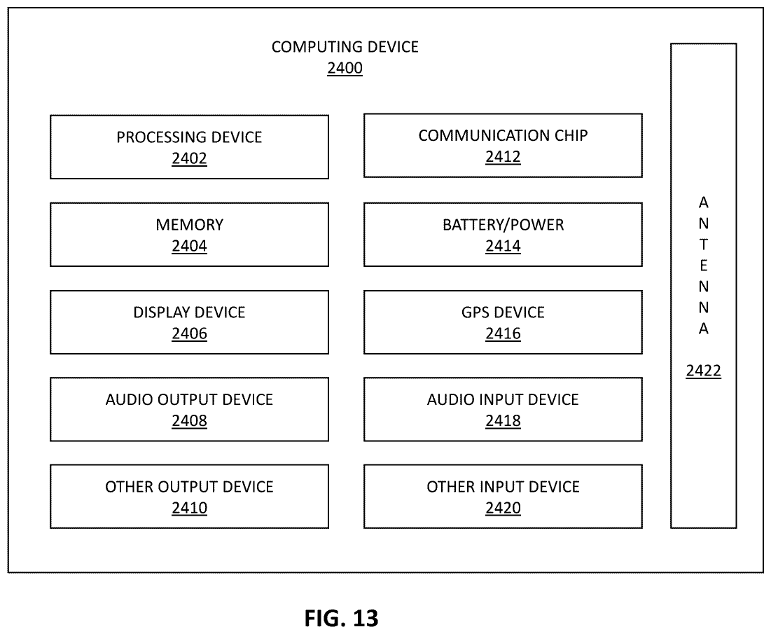

FIG. 13 is a block diagram of an example computing device 2400 that may include one or more components with one or more IC devices having CFET with forked semiconductor structure, according to some embodiments of the disclosure. For example, any suitable ones of the components of the computing device 2400 may include a die (e.g., the die 2002 of FIG. 10B) including CFET with forked semiconductor structure, according to some embodiments of the disclosure. Any of the components of the computing device 2400 may include CFET with forked semiconductor structure (e.g., any embodiment of CFET with forked semiconductor structure described above in conjunction with FIGS. 1, 3A, 3B, and 5A-5N) and/or an IC package (e.g., the IC package 2200 of FIG. 11). Any of the components of the computing device 2400 may include an IC device assembly (e.g., the IC device assembly 2300 of FIG. 12).

A number of components are illustrated in FIG. 13 as included in the computing device 2400, but any one or more of these components may be omitted or duplicated, as suitable for the application. In some embodiments, some or all of the components included in the computing device 2400 may be attached to one or more motherboards. In some embodiments, some or all of these components are fabricated onto a single SoC (system-on-chip) die.

Additionally, in various embodiments, the computing device 2400 may not include one or more of the components illustrated in FIG. 13, but the computing device 2400 may include interface circuitry for coupling to the one or more components. For example, the computing device 2400 may not include a display device 2406, but may include display device interface circuitry (e.g., a connector and driver circuitry) to which a display device 2406 may be coupled. In another set of examples, the computing device 2400 may not include an audio input device 2418 or an audio output device 2408, but may include audio input or output device interface circuitry (e.g., connectors and supporting circuitry) to which an audio input device 2418 or audio output device 2408 may be coupled.

The computing device 2400 may include a processing device 2402 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2402 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. The computing device 2400 may include a memory 2404, which may itself include one or more memory devices such as volatile memory (e.g., DRAM), nonvolatile memory (e.g., read-only memory (ROM)), flash memory, solid-state memory, and/or a hard drive. In some embodiments, the memory 2404 may include memory that shares a die with the processing device 2402. This memory may be used as cache memory and may include, e.g., eDRAM, and/or spin transfer torque magnetic random-access memory (STT-MRAM).

In some embodiments, the computing device 2400 may include a communication chip 2412 (e.g., one or more communication chips). For example, the communication chip 2412 may be configured for managing wireless communications for the transfer of data to and from the computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2412 may operate in accordance with other wireless protocols in other embodiments. The computing device 2400 may include an antenna 2422 to facilitate wireless communications and/or to receive other wireless communications (such as AM or FM radio transmissions).

In some embodiments, the communication chip 2412 may manage wired communications, such as electrical, optical, or any other suitable communication protocols (e.g., the Ethernet). As noted above, the communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

In various embodiments, IC devices having CFET with forked semiconductor structure as described herein may be particularly advantageous for use as part of ESD circuits protecting power amplifiers, low-noise amplifiers, filters (including arrays of filters and filter banks), switches, or other active components. In some embodiments, IC devices having CFET with forked semiconductor structure as described herein may be used in PMICs, e.g., as a rectifying diode for large currents. In some embodiments, IC devices having CFET with forked semiconductor structure as described herein may be used in audio devices and/or in various input/output devices.

The computing device 2400 may include battery/power circuitry 2414. The battery/power circuitry 2414 may include one or more energy storage devices (e.g., batteries or capacitors) and/or circuitry for coupling components of the computing device 2400 to an energy source separate from the computing device 2400 (e.g., AC line power).

The computing device 2400 may include a display device 2406 (or corresponding interface circuitry, as discussed above). The display device 2406 may include any visual indicators, such as a heads-up display, a computer monitor, a projector, a touchscreen display, a liquid crystal display (LCD), a light-emitting diode display, or a flat panel display, for example.

The computing device 2400 may include an audio output device 2408 (or corresponding interface circuitry, as discussed above). The audio output device 2408 may include any device that generates an audible indicator, such as speakers, headsets, or earbuds, for example.

The computing device 2400 may include an audio input device 2418 (or corresponding interface circuitry, as discussed above). The audio input device 2418 may include any device that generates a signal representative of a sound, such as microphones, microphone arrays, or digital instruments (e.g., instruments having a musical instrument digital interface (MIDI) output).

The computing device 2400 may include a GPS device 2416 (or corresponding interface circuitry, as discussed above). The GPS device 2416 may be in communication with a satellite-based system and may receive a location of the computing device 2400, as known in the art.

The computing device 2400 may include another output device 2410 (or corresponding interface circuitry, as discussed above). Examples of the other output device 2410 may include an audio codec, a video codec, a printer, a wired or wireless transmitter for providing information to other devices, or an additional storage device.

The computing device 2400 may include another input device 2420 (or corresponding interface circuitry, as discussed above). Examples of the other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, the computing device 2400 may be any other electronic device that processes data.

The following paragraphs provide various examples of the embodiments disclosed herein.

Example 1 provides an IC device, including a gate assembly including a first gate and a second gate, the second gate over the first gate in a first direction; a first source region at a first side of the gate assembly; a first drain region at a second side of the gate assembly, the second side opposing the first side in a second direction perpendicular to the first direction; a second source region at the first side of the gate assembly; and a second drain region at the second side of the gate assembly, where the first gate is between the first source region and the first drain region in the second direction, the second gate is between the second source region and the second drain region in the second direction, at least part of the first source region is over at least part of the second source region in the first direction, and at least part of the first drain region is over at least part of the second drain region in the first direction.

Example 2 provides the IC device according to example 1, where at least one of the first source region, the first drain region, the second source region, and the second drain region has a forked structure, the forked structure including a first structure and a plurality of second structures, and an individual second structure protrudes from a surface of the first structure and is over another individual second structure in the first direction.

Example 3 provides the IC device according to example 2, further including an electrically conductive structure over the first section in the first direction.

Example 4 provides the IC device according to example 3, further including a layer including an electrically conductive material, where the layer is closer to the first source region than the second source region, and the electrically conductive structure is electrically coupled to the layer.

Example 5 provides the IC device according to any one of examples 2-4, where the first gate includes a plurality of gate electrodes that are separated from each other by one or more electrical insulators.

Example 6 provides the IC device according to any of the preceding examples, where the first gate, the first source region, and the first drain region are in a P-type FET, and the second gate, the second source region, and the second drain region are in an N-type FET.

Example 7 provides the IC device according to any of the preceding examples, where the gate assembly further includes an electrical insulator between the first gate and the second gate.

Example 8 provides an IC device, including a first semiconductor region including a first portion, a second portion, and a third portion, the third portion between the first portion and the second portion in a first direction; a second semiconductor region at a first side of the first semiconductor region, the second semiconductor region connected to the first portion of the first semiconductor region; a third semiconductor region at a second side of the first semiconductor region, the third semiconductor region connected to the second portion of the first semiconductor region, the first side opposing the second side in in a second direction that is perpendicular to the first direction; and an electrically conductive structure over the third portion of the first semiconductor region a third direction that is perpendicular to the first direction or the second direction.

Example 9 provides the IC device according to example 8, further including a first dielectric layer over the first portion and the third portion of the first semiconductor region in the second direction; and a second dielectric layer over the second portion and the third portion of the first semiconductor region in the second direction, where the electrically conductive structure is between a portion of the first dielectric layer and a portion of the second dielectric layer in the second direction.

Example 10 provides the IC device according to example 8 or 9, where the electrically conductive structure is a first electrically conductive structure, and the IC device further includes a second electrically conductive structure over the second semiconductor region in the third direction; and a third electrically conductive structure over the third semiconductor region in the third direction.

Example 11 provides the IC device according to example 10, further including a fourth electrically conductive structure over the second semiconductor region in the third direction, where the second semiconductor region is between the second electrically conductive structure and the fourth electrically conductive structure in the third direction.

Example 12 provides the IC device according to any one of examples 8-11, where the electrically conductive structure is separated from the third portion of the first semiconductor region by an electrical insulator.

Example 13 provides the IC device according to any one of examples 8-12, further including a fourth semiconductor region over the first semiconductor region in the third direction; and another electrically conductive structure over a portion of the fourth semiconductor region.

Example 14 provides the IC device according to any one of examples 8-13, where the first semiconductor region includes a fin or a nanoribbon.

Example 15 provides an IC device, including a structure including a plurality of electrically conductive structures; a first semiconductor region including a first body and a plurality of first branches extending from the first body; and a second semiconductor region including a second body and a plurality of second branches extending from the second body, where: the plurality of first branches is at a first side of the structure, the plurality of second branches is at a second side of the structure, the second side opposes the first side in a direction, and an individual electrically conductive structure is between an individual first branch and an individual second branch in the direction.

Example 16 provides the IC device according to example 15, further including a third semiconductor region including a third body and a plurality of third branches extending from the third body; and a fourth semiconductor region including a fourth body and a plurality of fourth branches extending from the fourth body, where the plurality of third branches is at the first side of the structure, the plurality of fourth branches is the second side of the structure, and another individual electrically conductive structure is between an individual third branch and an individual fourth branch.

Example 17 provides the IC device according to example 16, where the plurality of first branches or the plurality of second branches is over a first portion of the structure in the direction, the plurality of third branches or the plurality of fourth branches is over a second portion of the structure in the direction, and the first portion is over the second portion in another direction that is perpendicular to the direction.

Example 18 provides the IC device according to any one of examples 15-17, where the structure further includes a first dielectric layer and a second dielectric layer, and the plurality of electrically conductive structures is between a portion of the first dielectric layer and a second dielectric layer in another direction that is perpendicular to the direction.

Example 19 provides the IC device according to example 18, where another portion of the first dielectric layer is between a portion of an individual first branch and a portion of another individual first branch, and another portion of the second dielectric layer is between a portion of an individual second branch and a portion of another individual second branch.

Example 20 provides the IC device according to any one of examples 15-19, where an individual first branch or an individual second branch includes a fin or a nanoribbon.

Example 21 provides an IC package, including the IC device according to any one of examples 1-20; and a further IC component, coupled to the device.

Example 22 provides the IC package according to example 21, where the further IC component includes one of a package substrate, an interposer, or a further IC die.

Example 23 provides the IC package according to example 21 or 22, where the IC device according to any one of examples 1-20 may include, or be a part of, at least one of a memory device, a computing device, a wearable device, a handheld electronic device, and a wireless communications device.

Example 24 provides an electronic device, including a carrier substrate; and one or more of the IC device according to any one of examples 1-20 and the IC package according to any one of examples 21-23, coupled to the carrier substrate.

Example 25 provides the electronic device according to example 24, where the carrier substrate is a motherboard.

Example 26 provides the electronic device according to example 24, where the carrier substrate is a PCB.

Example 27 provides the electronic device according to any one of examples 24-26, where the electronic device is a wearable electronic device or handheld electronic device.

Example 28 provides the electronic device according to any one of examples 24-27, where the electronic device further includes one or more communication chips and an antenna.

Example 29 provides the electronic device according to any one of examples 24-28, where the electronic device is an RF transceiver.

Example 30 provides the electronic device according to any one of examples 24-28, where the electronic device is one of a switch, a power amplifier, a low-noise amplifier, a filter, a filter bank, a duplexer, an upconverter, or a downconverter of an RF communications device, e.g., of an RF transceiver.

Example 31 provides the electronic device according to any one of examples 24-30, where the electronic device is a computing device.

Example 32 provides the electronic device according to any one of examples 24-31, where the electronic device is included in a base station of a wireless communication system.

Example 33 provides the electronic device according to any one of examples 24-31, where the electronic device is included in a user equipment device of a wireless communication system.

Example 34 provides processes for forming the IC device according to any one of claims 1-20.

Example 35 provides processes for forming the IC package according to any one of the claims 21-23.

Example 36 provides processes for forming the electronic device according to any one of the claims 24-33.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) device, comprising:
a gate assembly comprising a first gate and a second gate, the second gate over the first gate in a first direction;
a first source region at a first side of the gate assembly;
a first drain region at a second side of the gate assembly, the second side opposing the first side in a second direction perpendicular to the first direction;
a second source region at the first side of the gate assembly; and
a second drain region at the second side of the gate assembly,
wherein:
the first gate is between the first source region and the first drain region in the second direction,
the second gate is between the second source region and the second drain region in the second direction,
at least part of the first source region is over at least part of the second source region in the first direction, and
at least part of the first drain region is over at least part of the second drain region in the first direction.

2. The IC device according to claim 1, wherein:
at least one of the first source region, the first drain region, the second source region, and the second drain region has a forked structure,
the forked structure comprising a first section and a plurality of second sections, and
an individual second section protrudes from a surface of the first section and is over another individual second section in the first direction.

3. The IC device according to claim 2, further comprising:
an electrically conductive structure over the first section in the first direction.

4. The IC device according to claim 3, further comprising:
a layer comprising an electrically conductive material,
wherein the layer is closer to the first source region than the second source region, and the electrically conductive structure is electrically coupled to the layer.

5. The IC device according to claim 2, wherein the first gate comprises a plurality of gate electrodes that are separated from each other by one or more electrical insulators.

6. The IC device according to claim 1, wherein:
the first gate, the first source region, and the first drain region are in a P-type field-effect transistor, and
the second gate, the second source region, and the second drain region are in an N-type field-effect transistor.

7. The IC device according to claim 1, wherein the gate assembly further comprises an electrical insulator between the first gate and the second gate.

8. An integrated circuit (IC) device, comprising:
a first semiconductor region, comprising a first portion, a second portion, and a third portion, the third portion between the first portion and the second portion in a first direction;
a second semiconductor region at a first side of the first semiconductor region, the second semiconductor region connected to the first portion of the first semiconductor region;
a third semiconductor region at a second side of the first semiconductor region, the third semiconductor region connected to the second portion of the first semiconductor region, the first side opposing the second side in a second direction that is perpendicular to the first direction; and
an electrically conductive structure over the third portion of the first semiconductor region a third direction that is perpendicular to the first direction or the second direction.

9. The IC device according to claim 8, further comprising:
a first dielectric layer over the first portion and the third portion of the first semiconductor region in the second direction; and
a second dielectric layer over the second portion and the third portion of the first semiconductor region in the second direction,
wherein the electrically conductive structure is between a portion of the first dielectric layer and a portion of the second dielectric layer in the second direction.

10. The IC device according to claim 8, wherein the electrically conductive structure is a first electrically conductive structure, and the IC device further comprises:
a second electrically conductive structure over the second semiconductor region in the third direction; and
a third electrically conductive structure over the third semiconductor region in the third direction.

11. The IC device according to claim 10, further comprising:
a fourth electrically conductive structure over the second semiconductor region in the third direction,
wherein the second semiconductor region is between the second electrically conductive structure and the fourth electrically conductive structure in the third direction.

12. The IC device according to claim 8, wherein the electrically conductive structure is separated from the third portion of the first semiconductor region by an electrical insulator.

13. The IC device according to claim 8, further comprising:
a fourth semiconductor region over the first semiconductor region in the third direction; and
another electrically conductive structure over a portion of the fourth semiconductor region.

14. The IC device according to claim 8, wherein the first semiconductor region comprises a fin or a nanoribbon.

15. An integrated circuit (IC) device, comprising:
a structure comprising a plurality of electrically conductive structures;
a first semiconductor region comprising a first body and a plurality of first branches extending from the first body; and
a second semiconductor region comprising a second body and a plurality of second branches extending from the second body, wherein
wherein:
the plurality of first branches is at a first side of the structure,
the plurality of second branches is at a second side of the structure,
the second side opposes the first side in a direction, and
an individual electrically conductive structure is between an individual first branch and an individual second branch in the direction.

16. The IC device according to claim 15, further comprising:
a third semiconductor region comprising a third body and a plurality of third branches extending from the third body; and
a fourth semiconductor region comprising a fourth body and a plurality of fourth branches extending from the fourth body,
wherein the plurality of third branches is at the first side of the structure, the plurality of fourth branches is the second side of the structure, and another individual electrically conductive structure is between an individual third branch and an individual fourth branch.

17. The IC device according to claim 16, wherein:
the plurality of first branches or the plurality of second branches is over a first portion of the structure in the direction,
the plurality of third branches or the plurality of fourth branches is over a second portion of the structure in the direction, and
the first portion is over the second portion in another direction that is perpendicular to the direction.

18. The IC device according to claim 15, wherein the structure further comprises a first dielectric layer and a second dielectric layer, and the plurality of electrically conductive structures is between a portion of the first dielectric layer and a second dielectric layer in another direction that is perpendicular to the direction.

19. The IC device according to claim 18, wherein:
another portion of the first dielectric layer is between a portion of an individual first branch and a portion of another individual first branch, and
another portion of the second dielectric layer is between a portion of an individual second branch and a portion of another individual second branch.

20. The IC device according to claim 15, wherein an individual first branch or an individual second branch comprises a fin or a nanoribbon.
